(19) United States
(12) Patent Application Publication
(10) Pub. No.: US 2025/0089529 A1
(43) Pub. Date: Mar. 13, 2025

(54) DISPLAY APPARATUS AND METHOD OF MANUFACTURING THE SAME

(71) Applicant: Samsung Display Co., LTD., Yongin-si (KR)

(72) Inventors: Sungyong KANG, Yongin-si (KR); Seulgi KIM, Yongin-si (KR); Doohyun KIM, Yongin-si (KR); Yejin KIM, Yongin-si (KR)

(21) Appl. No.: 18/665,927

(22) Filed: May 16, 2024

(30) Foreign Application Priority Data
Sep. 12, 2023 (KR) 10-2023-0121346

(51) Int. Cl. H10K 59/80; H10K 59/12

(52) U.S. Cl. CPC H10K 59/873; H10K 59/1201

(57) ABSTRACT

Provided is a method of manufacturing a display apparatus including, in a display panel including a central area and a peripheral area surrounding the central area, arranging a first adhesive material layer along the peripheral area of the display panel, arranging a second adhesive material layer such that the second adhesive material layer overlaps the central area and a first portion of the first adhesive material layer, and arranging a third adhesive material layer on a second portion of the first adhesive material layer opposite to the first portion, wherein the third adhesive material layer is apart from the second adhesive material layer.

This application claims priority to Korean Patent Application No. 10-2023-0121346, filed on Sep. 12, 2023, and all the benefits accruing therefrom under 35 U.S.C. § 119, the content of which in its entirety is herein incorporated by reference.

### BACKGROUND

### 1. Field

Embodiments supported by aspects of the present disclosure relate to a display apparatus, and particularly, to a display apparatus including a light-emitting diode and a method of manufacturing the display apparatus.

### 2. Description of the Related Art

A display apparatus may visually display data. Some display apparatuses may include a display panel separated into a central area and a peripheral area. In some cases, a plurality of subpixels may be arranged in the central area. Each of the plurality of subpixels may include a light-emitting diode. An image may be displayed in the central area through light emitted from the light-emitting diodes. The peripheral area may include various wires, drivers, controllers, and other components that transmit electrical signals to the central area. In some cases, no image is displayed in the peripheral area.

A window to protect the display panel may be placed on the display panel. The window may be attached to the display panel through an adhesive layer.

### SUMMARY

An adhesive layer between a display panel and a window may be formed using a liquid adhesive having a certain viscosity. The adhesive may be applied to the display panel in a liquid state. Since the adhesive has viscosity, the adhesive may form a certain inclination around an edge of the display panel (e.g., a peripheral area). When attaching the window to the display panel, to prevent a space from being generated between the window and the display panel due to the inclination of the adhesive when attaching the window to the display panel, an adhesive may be additionally applied to the peripheral area. In this case, if the additional adhesive is too wide, the contour thereof may extend to the central area beyond the peripheral area and may be a line shape visible to the user.

Additional aspects will be set forth in part in the description which follows and, in part, will be apparent from the description, or may be learned by practice of the presented embodiments of the disclosure.

According to one or more embodiments, a display apparatus includes a display panel including a central area and a peripheral area surrounding the central area, a window disposed on the display panel, a first adhesive layer between the display panel and the window and arranged along the peripheral area of the display panel, a second adhesive layer between the display panel and the window and corresponding to the central area of the display panel, and a third adhesive layer between the display panel and the window and overlapping a portion of the upper surface of the first adhesive layer in the peripheral area of the display panel.

According to one or more embodiments, the second adhesive layer and the third adhesive layer may be apart from each other.

According to one or more embodiments, in a cross-sectional view, the first adhesive layer may include a peak where a thickness of the first adhesive layer is greatest, a first portion between the peak and a first edge adjacent to the central area, and a second portion between the peak and a second edge arranged opposite to the first edge, wherein the second adhesive layer may overlap the first portion, and the third adhesive layer may overlap the second portion.

According to one or more embodiments, a peak width of the third adhesive layer may be less than or equal to a width of the second portion.

According to one or more embodiments, the second adhesive layer may directly contact the first portion, and the third adhesive layer may directly contact the second portion.

According to one or more embodiments, the display apparatus may further include a fourth adhesive layer between the display panel and the window and between the first adhesive layer and the second adhesive layer.

According to one or more embodiments, the fourth adhesive layer may directly contact an upper surface of a portion of the first adhesive layer and directly contact an upper surface of a portion of the second adhesive layer.

According to one or more embodiments, in a plan view, at least one of the first adhesive layer and the third adhesive layer may surround the central area.

According to one or more embodiments, a method of manufacturing a display apparatus may include, in a display panel including a central area and a peripheral area surrounding the central area, arranging a first adhesive material layer along the peripheral area of the display panel, arranging a second adhesive material layer such that the second adhesive material layer overlaps the central area and a first portion of the first adhesive material layer, and arranging a third adhesive material layer on a second portion of the first adhesive material layer opposite to the first portion, wherein the third adhesive material layer is apart from the second adhesive material layer.

According to one or more embodiments, in a cross-sectional view, the first adhesive material layer may include a peak where a thickness is greatest, the first portion between the peak and a first edge adjacent to the central area, and the second portion between the peak and a second edge opposite to the first edge, wherein the second adhesive material layer may directly contact an upper surface of the first portion, and the third adhesive material layer may directly contact an upper surface of the second portion.

According to one or more embodiments, a distance measured from an edge of the third adhesive material layer to another edge of the third adhesive material layer along a direction parallel to the upper surface of the display panel may be less than or equal to a width of the second portion.

According to one or more embodiments, in a plan view, at least one of the first adhesive material layer and the third adhesive material layer may surround the central area.

According to one or more embodiments, a method of manufacturing a display apparatus may further include semi-hardening the first adhesive material layer by irradiating the first adhesive material layer with light, and semi-hardening the second adhesive material layer and the third adhesive material layer by irradiating the second adhesive material layer and the third adhesive material layer with the light, wherein an elastic modulus of the semi-hardened second adhesive material layer and an elastic modulus of the semi-hardened third adhesive material layer may be different from an elastic modulus of the semi-hardened first adhesive material layer.

According to one or more embodiments, a method of manufacturing a display apparatus includes, in a display panel including a central area and a peripheral area surrounding the central area, arranging a first adhesive material layer along the peripheral area of the display panel, arranging a second adhesive material layer on the display panel apart from the first adhesive material layer and correspondingly to the central area, arranging a third adhesive material layer on the first adhesive material layer, and arranging a fourth adhesive material layer between the first adhesive material layer and the second adhesive material layer.

According to one or more embodiments, in a cross-sectional view, the first adhesive material layer may include a peak where a thickness is greatest, a first portion between the peak and a first edge adjacent to the central area, and a second portion between the peak and a second edge opposite to the first edge.

According to one or more embodiments, the third adhesive material layer may directly contact an upper surface of the second portion, and the fourth adhesive material layer may directly contact an upper surface of the first portion.

According to one or more embodiments, a distance measured from an edge of the third adhesive material layer to another edge of the third adhesive material layer along a direction parallel to the upper surface of the display panel may be equal to or less than a width of the second portion.

According to one or more embodiments, the second adhesive material layer and the third adhesive material layer may be apart from each other.

According to one or more embodiments, the method of manufacturing a display apparatus may further include semi-hardening the first adhesive material layer and the second adhesive material layer by irradiating the first adhesive material layer and the second adhesive material layer with light, and semi-hardening the third adhesive material layer and the fourth adhesive material layer by irradiating the third adhesive material layer and the fourth adhesive material layer with the light.

According to one or more embodiments, an elastic modulus of the semi-hardened first adhesive material layer and an elastic modulus of the semi-hardened second adhesive material layer may be different from an elastic modulus of the semi-hardened third adhesive material layer and an elastic modulus of the semi-hardened fourth adhesive material layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a plan view of a portion of the display apparatus according to an embodiment;

FIG. 3A is a schematic plan view of the display apparatus according to an embodiment;

FIG. 3B is a schematic cross-sectional view of a portion of the display apparatus taken along line III-III′ of FIG. 3A;

FIG. 4A is a schematic plan view of the display apparatus according to an embodiment;

FIG. 4B is a schematic cross-sectional view of a portion of the display apparatus taken along line IV-IV′ of FIG. 4A, according to some embodiments;

FIGS. 5A, 5C, and 5D are each a plan view of the display apparatus in a processing state of a method of manufacturing the display apparatus according to an embodiment;

FIGS. 5B, 5E, and 5F are each a cross-sectional view of the display apparatus in a processing state of the method of manufacturing the display apparatus according to an embodiment;

FIG. 6A is a schematic plan view of a display apparatus according to an embodiment.

FIG. 6B is a schematic cross-sectional view of a portion of the display apparatus taken along line VI-VI′ of FIG. 6A, according to some embodiments;

FIGS. 7A, 7C, and 7D are each a plan view of the display apparatus in a processing state of a method of manufacturing the display apparatus according to some embodiments;

FIGS. 7B, 7E, and 7F are each a cross-sectional view of the display apparatus in a processing state of the method of manufacturing the display apparatus according to some embodiments;

FIGS. 8A and 8B are each a plan view and a cross-sectional view of an enlarged central area in a processing state of the method of manufacturing the display apparatus according to an embodiment;

FIG. 9 is a graph showing an elastic modulus according to a semi-hardening rate;

FIG. 10 is a graph showing a visibility of a striped stain according to the semi-hardening rate;

FIG. 11 is a graph showing an application profile of an adhesive material layer according to the prior art and an application profile of an adhesive material layer according to an embodiment of the disclosure; and

FIG. 12 is a plan view of the display apparatus manufactured by applying the adhesive material layer according to the prior art.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, preferred embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

One or more embodiments of the disclosure will be described below in more detail with reference to the accompanying drawings. Those elements that are the same or are in correspondence are rendered the same reference numeral regardless of the figure number, and redundant descriptions thereof are omitted.

In the specification, the terms “first” and “second” are not used in a limited sense and are used to distinguish one component from another component.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

In the drawings, for convenience of description, sizes of components may be exaggerated or reduced. In other words, since sizes and thicknesses of elements in the drawings are arbitrarily illustrated for convenience of description, the following embodiments are not limited thereto.

When a certain embodiment may be implemented differently, a specific process order may be performed differently from the described order. For example, two consecutively described processes may be performed substantially at the same time or performed in an order opposite to the described order.

In the specification, “A and/or B” denotes only A, only B, or both A and B. Also, the expression “at least one of A and B” may indicate A, B, or A and B.

In the embodiments hereinafter, it will be understood that when an element, an area, or a layer is referred to as being connected to another element, area, or layer, it can be directly and/or indirectly connected to the other element, area, or layer. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

In the following examples, the x-axis, the y-axis and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

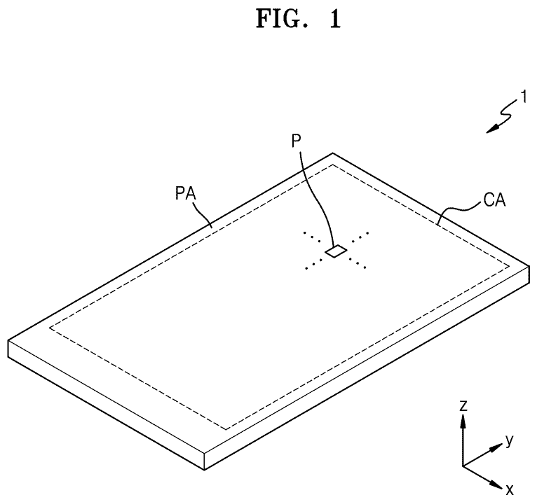

FIG. 1 is a schematic perspective view of a display apparatus according to an embodiment.

Referring to FIG. 1, a display apparatus 1 may include a central area CA and a peripheral area PA located outside of the central area CA. The central area CA may display an image through a subpixel P arranged in the central area CA. The subpixel P may display an image by using a light-emitting diode corresponding to the subpixel P. The peripheral area PA is arranged in the outside of the central area CA, does not display an image, and may surround the entire central area CA. A driver and/or other components for supporting electric signal or power to the central area CA may be arranged in the peripheral area PA. A pad wherein an electronic device, a printed circuit board, or the like are electrically connected to the pad may be arranged in the peripheral area PA.

In an embodiment, FIG. 1 illustrates a polygon (e.g., a rectangle) of which the length in the x direction of the central area CA is less than the length in the y direction of the central area CA. However, in some embodiments, the polygon (e.g., a rectangle) may have a central area of which the length in the y direction is less than the length in the x direction. FIG. 1 illustrates that the central area CA is substantially rectangular, but embodiments are not limited thereto. In some embodiments, the central area CA may have various shapes such as, for example, an N-gon (where N is a natural number of 3 or more), a circle, or an oval. Although FIG. 1 illustrates that a corner of the central area CA includes a vertical point in which a straight line meets a straight line, according to some embodiments, one or more corners of the central area CA of the polygon may be a curved corner.

For convenience of explanation, cases wherein the display apparatus 1 is an electronic device, that is, for example, a smartphone, are described. However, the display apparatus 1 of the disclosure is not limited thereto. The display apparatus 1 may be applied to not only portable electronic devices such as, for example, a mobile phone, a smart phone, a tablet personal computer (PC), a mobile communication terminal, an electronic notepad, an electronic book, a portable multimedia player (PMP), a navigation device, an ultra mobile PC (UMPC), and the like, but also various products such as, for example, a television, a notebook computer, a monitor, a billboard, and internet of things (IoT) device. In some aspects, the display apparatus 1 according to an embodiment may be used in a wearable device, such as, for example, a smart watch, a watch phone, an eyewear display, and a head mounted display (HMD). In some aspects, the display apparatus 1 according to an embodiment may be applied to a dashboard of a vehicle, center information display (CID) arranged in a center fascia or dashboard of a vehicle, a room mirror display replacing the side mirror of a vehicle, and a display arranged on the rear surface of the front seat for entertainment in the back seat of a vehicle.

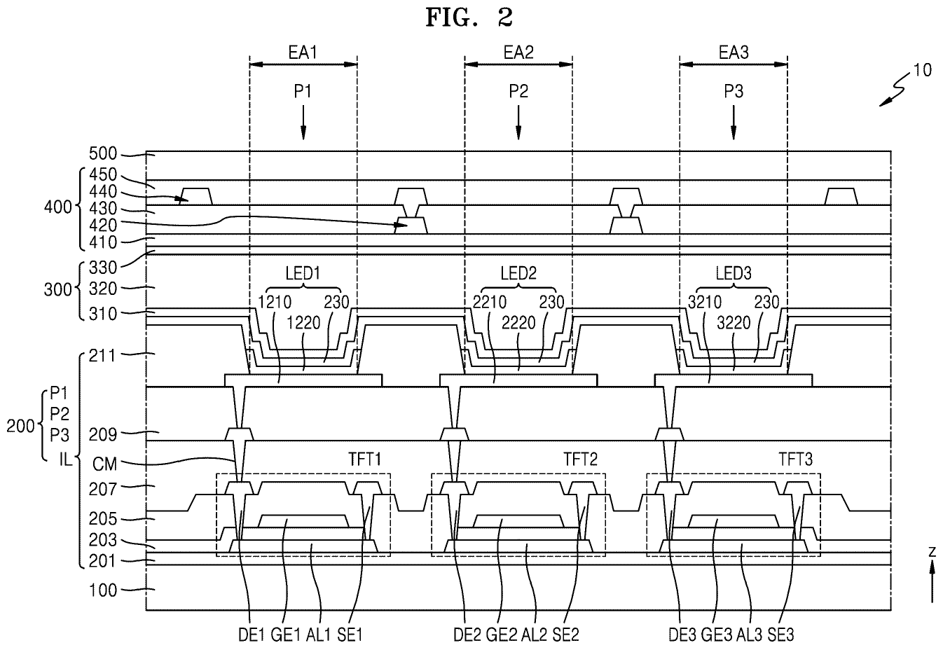

FIG. 2 is a plan view of a portion of the display apparatus according to an embodiment.

Referring to FIG. 2, a display panel 10 may include a substrate 100, a display layer 200 disposed on the substrate 100, an encapsulation layer 300 disposed on the display layer 200, a touch layer 400 disposed on the encapsulation layer 300, and an optical functional layer 500 disposed on the touch layer 400.

The display layer 200 may include a plurality of subpixels and an insulating layer IL and may be disposed on the substrate 100. In an embodiment, first to third subpixels P1, P2, and P3 (hereinafter, also referred to as the first subpixel P1, the second subpixel P2, and the third subpixel P3) may be disposed on the substrate 100. The first to third subpixels P1, P2, and P3 may include first to third light-emitting diodes LED1, LED2, and LED3 each capable of emitting light of a constant color.

The first to third light-emitting diodes LED1, LED2, and LED3 may respectively include first to third subpixel electrodes 1210, 2210, and 3210 (hereinafter, also referred to as the first subpixel electrode 1210, the second subpixel electrode 2210, and the third subpixel electrode 3210) and first to third interlayers 1220, 2220, and 3220 (hereinafter, also referred to as the first interlayer 1220, the second interlayer 2220, and the third interlayer 3220) that respectively correspond to the first to third light-emitting diodes LED1, LED2, and LED3.

The substrate 100 may include glass or plastic polymer resins. In an example, in which the substrate 100 includes a polymer resin, the substrate 100 may have flexible, rollable, or bendable characteristics. The substrate 100 may form a multilayer structure including a layer including a polymer resin and an inorganic layer (not shown).

The first to third interlayers 1220, 2220, and 3220 corresponding to the first to third subpixels P1, P2, and P3, respectively, may be electrically connected to first to third thin-film transistors TFT1, TFT2, and TFT3 (hereinafter, also referred to as the first thin-film transistor TFT1, the second thin-film transistor TFT2, and the third thin-film transistor TFT3), respectively.

The first interlayer 1220 corresponding to the first subpixel P1 may be electrically connected to the first thin-film transistor TFT1 through the first subpixel electrode 1210. The first thin-film transistor TFT1 may include a first active layer AL1, a first gate electrode GE1 overlapping a portion of the first active layer AL1, and a first source electrode SE1 and a first drain electrode DE1 each directly contacting a portion of the first active layer AL1.

The second interlayer 2220 corresponding to the second subpixel P2 may be electrically connected to the second thin-film transistor TFT2 through the second subpixel electrode 2210. The second thin-film transistor TFT2 may include a second active layer AL2, a second gate electrode GE2 overlapping a portion of the second active layer AL2, and a second source electrode SE2 and a second drain electrode DE2 each directly contacting a portion of the second active layer AL2.

The third interlayer 3220 corresponding to the third subpixel P3 may be electrically connected to the third thin-film transistor TFT3 through the third subpixel electrode 3210. The third thin-film transistor TFT3 may include a third active layer AL3, a third gate electrode GE3 overlapping a portion of the third active layer AL3, and a third source electrode SE3 and a third drain electrode DE3 each directly contacting a portion of the third active layer AL3.

The first gate electrode GE1, the second gate electrode GE2, and the third gate electrode GE3 may have a single layer or a multilayer structure including at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The display panel 10 may include a buffer layer 201 arranged between the first active layer AL1, a second active layer AL2, and a third active layer AL3 and the substrate 100. The buffer layer 201 may prevent penetration of impurities. The display panel 10 may include a gate insulating layer 203 arranged between the first active layer AL1 and the first gate electrode GE1, between the second active layer AL2 and the second gate electrode GE2, and between the third active layer AL3 and the third gate electrode GE3. The display panel 10 may include an interlayer insulating layer 205 arranged on the first gate electrode GE1, the second gate electrode GE2, and the third gate electrode GE3. Each of the buffer layer 201, the gate insulating layer 203, and the interlayer insulating layer 205 may include inorganic insulating materials such as, for example, silicon oxide (SiOₓ), silicon nitride (SiNₓ), silicon oxynitride (SiON), aluminum oxide (Al₂O₃), aluminum nitride (AlNₓ), titanium oxide (TiO₂), titanium nitride (TiNₓ), or the like.

The first source electrode SE1, the second source electrode SE2, and the third source electrode SE3 may be arranged on the interlayer insulating layer 205 and may be connected to the first active layer AL1, the second active layer AL2, and the third active layer AL3, respectively, through contact holes formed in the interlayer insulating layer 205 and the gate insulating layer 203. The first source electrode SE1, the second source electrode SE2, and the third source electrode SE3 may include Al, Pt, Pd, Ag, Mg, Au, Ni, Nd, Ir, Cr, Li, Ca, Mo, Ti, W, or Cu, and may have a single layer or a multilayer structure.

The first drain electrode DE1, the second drain electrode DE2, and the third drain electrode DE3 may be arranged on the interlayer insulating layer 205, and may be connected to the first active layer AL1, the second active layer AL2, and the third active layer AL3, respectively, through contact holes formed in the interlayer insulating layer 205 and the gate insulating layer. The first drain electrode DE1, the second drain electrode DE2, and the third drain electrode DE3 may each include Al, Pt, Pd, Ag, Mg, Au, Ni, Nd, Ir, Cr, Li, Ca, Mo, Ti, W, or Cu, and may have a single layer or a multilayer structure. In some embodiments, the first source electrode SE1, the second source electrode SE2, and the third source electrode SE3 and the first drain electrode DE1, the second drain electrode DE2, and the third drain electrode DE3 may include the same material. For example, the source electrode of a given thin-film transistor (e.g., first source electrode SE1 of first thin-film transistor TFT1) may include the same material as a drain electrode (e.g., first drain electrode DE1) of the thin-film transistor.

The first organic insulating layer 207 may be disposed on the first to third thin-film transistors TFT1, TFT2, and TFT3. For example, the first organic insulating layer 207 may cover the first source electrode SE1, the second source electrode SE2, and the third source electrode SE3 and the first drain electrode DE1, the second drain electrode DE2, and the third drain electrode DE3. The first organic insulating layer 207 may include an organic insulating material such as, for example, acryl, benzocyclobutene, polyimide, or hexamethyldisiloxane. The first organic insulating layer 207 may include a plurality of contact holes. For example, the first organic insulating layer 207 may include a plurality of contact holes respectively overlapping the first drain electrode DE1, the second drain electrode DE2, and the third drain electrode DE3.

The display panel 10 may include a contact metal CM disposed on the first organic insulating layer 207. The contact metal CM may include materials such as, for example, Al, Cu, and/or Ti, and may be formed as a single layer or multilayer structure including the materials. The display panel 10 may include a plurality of contact metals CM, and the contact metals CM may respectively overlap the first drain electrode DE1, the second drain electrode DE2, and the third drain electrode DE3. A portion of each of the contact metals CM may be disposed in respective contact holes formed in the first organic insulating layer 207. For example, each contact metal CM may directly contact each of the first drain electrode DE1, the second drain electrode DE2, and the third drain electrode DE3 through a contact hole formed in the first organic insulating layer 207.

The display panel 10 may include a second organic insulating layer 209 arranged between the first organic insulating layer 207 and the first to third subpixel electrodes 1210, 2210, and 3210. The second organic insulating layer 209 may include an organic insulating material such as, for example, acryl, benzocyclobutene, polyimide, or hexamethyldisiloxane. The second organic insulating layer 209 may include contact holes respectively overlapping the contact metals CM.

The first to third subpixel electrodes 1210, 2210, and 3210 may be disposed on the second organic insulating layer 209. The first to third subpixel electrodes 1210, 2210, and 3210 may be formed as reflective electrodes. The first to third subpixel electrodes 1210, 2210, and 3210 may be formed by forming a reflective layer with Ag, Mg, Al, Pt, Pd, Au, Ni, Nd, Ir, Cr or compounds thereof and then disposing a film including indium tin oxide (ITO), indium zinc oxide (IZO), zinc oxide (ZnO), or indium oxide (In₂O₃) on the reflective layer. In an embodiment, the first to third subpixel electrodes 1210, 2210, and 3210 may have a structure in which an ITO layer, an AG layer, and an ITO layer are sequentially stacked. Embodiments of the present disclosure are not limited thereto, and the first to third subpixel electrodes 1210, 2210, and 3210 may be formed with various materials and be modified to various structures such as, for example, a single layer or multilayer structure.

The first to third subpixel electrodes 1210, 2210, and 3210 may be electrically connected, through the contact holes formed in the second organic insulating layer 209, to the contact metals CM respectively overlapping the contact holes formed in the second organic insulating layer 209.

Although according to an embodiment described with reference to FIG. 2, although the first to third thin-film transistors TFT1, TFT2, and TFT3 are electrically connected to the first to third subpixel electrodes 1210, 2210, and 3210, respectively through the contact metal CM, embodiments of the present disclosure are not limited thereto. In some embodiments, the contact metal CM may be omitted, and a single organic insulating layer may be arranged between the first to third thin-film transistors TFT1, TFT2, and TFT3 and the first to third subpixel electrodes 1210, 2210, and 3210. Alternatively, for example, three or more organic insulating layers may be arranged between the first to third thin-film transistors TFT1, TFT2, and TFT3 and the first to third subpixel electrodes 1210, 2210, and 3210, and the first to third thin-film transistors TFT1, TFT2, and TFT3 may be electrically connected to the first to third subpixel electrodes 1210, 2210, and 3210, respectively, through the organic insulating layers. That is, for example, a single organic insulating layer or multiple organic insulating layers may be arranged between a given thin-film transistor (e.g., first thin-film transistor TFT1) and a corresponding subpixel electrode (e.g., subpixel electrode 1210), and the thin-film transistor may be electrically connected to the corresponding subpixel electrode through the single organic insulating layer or multiple organic insulating layers.

The display panel 10 may include a subpixel defining layer 211 covering edge areas (or edges) of the first to third subpixel electrodes 1210, 2210, and 3210. In other words, for example, the subpixel defining layer 211 may include a plurality of openings exposing the central portion of each of the first to third subpixel electrodes 1210, 2210, and 3210. Each opening of the subpixel defining layer 211 may define a respective emission area of the first to third subpixels P1, P2, and P3. For example, the openings of the subpixel defining layer 211 may respectively define first to third emission areas EA1, EA2, and EA3 corresponding to the first to third subpixels P1, P2, and P3.

The first to third interlayers 1220, 2220, and 3220 may be respectively disposed on the first to third subpixel electrodes 1210, 2210, and 3210. For example, the first interlayer 1220 may be disposed on the first subpixel electrode 1210 in the opening of the subpixel defining layer 211. The second interlayer 2220 may be disposed on the second subpixel electrode 2210 in the opening of the subpixel defining layer 211. The third interlayer 3220 may be disposed on the third subpixel electrode 3210 in the opening of the subpixel defining layer 211.

The first to third interlayers 1220, 2220, and 3220 may each include an emission layer including a low-molecular or high-molecular material. The first to third interlayers 1220, 2220, and 3220 may each have a single layer or multilayer structure including a hole injection layer, a hole transport layer, an emission layer, an electron transport layer, and/or an electron injection layer.

The display panel 10 may include an opposite electrode 230 disposed on each of the first to third interlayers 1220, 2220, and 3220. The opposite electrode 230 may be integrally formed to cover the first to third interlayers 1220, 2220, and 3220. The opposite electrode 230 may be provided as a transparent (or transflective) electrode. In an example, of a transparent (or transflective) opposite electrode 230, the opposite electrode 230 may include one or more materials selected from Ag, Al, Mg, Li, Ca, Cu, LiF/Ca, LiF/Al, MgAg, and CaAg, and may be a thin film having a thickness of several to dozens of nanometers (nm). The structure and materials of the opposite electrode 230 are not limited thereto, and various modifications are possible.

The encapsulation layer 300 may be disposed on the opposite electrode 223. The encapsulation layer 300 may include at least one inorganic encapsulation layer and at least one organic encapsulation layer. For example, as shown in FIG. 2, the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include inorganic insulating materials such as, for example, SiOₓ, SiN_{X}, SiON, Al₂O₃, TiO₂, tantalum oxide (Ta₂O₅), hafnium oxide (HfO₂), zinc oxide (ZnO), or the like. The first inorganic encapsulation layer 310 and the second inorganic encapsulation layer 330 may each have a single layer or multilayer structure including one or more of the inorganic insulating materials.

The organic encapsulation layer 320 may alleviate an internal stress of the first inorganic encapsulation layer 310 and/or the second inorganic encapsulation layer 330. The organic encapsulation layer 320 may include a polymer-based material. For example, the organic encapsulation layer 320 may include polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, or the like), or a combination thereof.

The encapsulation layer 300 may have a multilayer structure including the first inorganic encapsulation layer 310, the organic encapsulation layer 320, and the second inorganic encapsulation layer 330. In this case, even if a crack is generated in the encapsulation layer 300, the multilayer structure may prevent the formation of cracks between the first inorganic encapsulation layer 310 and the organic encapsulation layer 320 and/or between the organic encapsulation layer 320 and the second inorganic encapsulation layer 330. The encapsulation layer 300 may prevent or minimize the penetration of external moisture or oxygen into the display layer 200.

Although not shown in FIG. 2, in some embodiments of the disclosure, the display panel 10 may further include a capping layer arranged between the encapsulation layer 300 and the opposite electrode 230. For example, in some embodiments of the disclosure, the display panel 10 may further include a capping layer (not shown) between the first inorganic encapsulation layer 310 and the opposite electrode 230. The capping layer may improve the light emission efficiency of the first to third light-emitting diodes LED1, LED2, and LED3 by the principle of constructive interference.

The touch layer 400 may be disposed on the encapsulation layer 300. The touch layer 400 may include a first touch insulating layer 410, a first conductive layer 420, a second touch insulating layer 430, a second conductive layer 440, and a third touch insulating layer 450.

The first touch insulating layer 410 may be disposed on the second inorganic encapsulation layer 330 of the encapsulation layer 300 and planarize a surface on which the first conductive layer 420 is disposed. The first touch insulating layer 410 may include an inorganic insulating material such as, for example, SiOₓ, SiNₓ, SiON, and the like. In some embodiments, the first touch insulating layer 410 may include an organic insulating material. In some embodiments, the first touch insulating layer 410 may be omitted, and the first conductive layer 420 may be disposed on the second inorganic encapsulation layer 330 of the encapsulation layer 300.

The second touch insulating layer 430 may be disposed on the first conductive layer 420. The second touch insulating layer 430 may include an inorganic or organic material. In an example in which the second touch insulating layer 430 is an inorganic material, the second touch insulating layer 430 may include at least one material selected from a group including silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), and silicon oxynitride (SiON). In an example in which the second touch insulating layer 430 is an organic material, the second touch insulating layer 430 may include at least one material selected from a group including acrylic resin, methacrylic resin, polyisoprene, vinyl resin, epoxy resin, urethane resin, cellulosic resin, and perylene resin.

The second conductive layer 440 may be disposed on the second touch insulating layer 430. The second conductive layer 440 may act as a sensor to detect a touch input of a user. The second conductive layer 440 may support detecting a touch input of the user. The first conductive layer 420 may act as a connector that connects the patterned second conductive layer 440 in a direction. The first conductive layer 420 may support electrical connection of the patterned second conductive layer 440 and one or more other layers or components. In an embodiment, both the first conductive layer 420 and the second conductive layer 440 may act as sensors. In this case, the first conductive layer 420 and the second conductive layer 440 may be electrically connected to each other through a contact hole. In an example in which both the first conductive layer 420 and the second conductive layer 440 act as sensors, the resistance of a touch electrode may be reduced, and the display panel 10 may support relatively quick detection of the touch input of the user.

In an embodiment, the first conductive layer 420 and the second conductive layer 440 may have a structure through which light emitted from the light-emitting diode may pass. For example, the first conductive layer 420 and the second conductive layer 440 may have a mesh structure. In this case, the first conductive layer 420 and the second conductive layer 440 may not overlap the emission area of the light-emitting diode.

The first conductive layer 420 and the second conductive layer 440 may include a metal layer or a transparent conductive layer. The metal layer may include Mo, Ag, Ti, Cu, Al, and an alloy thereof. The transparent conductive layer may include transparent conductive oxides such as, for example, ITO, IZO, ZnO, indium tin zinc oxide (ITZO), conductive polymers such as, for example, poly-(3,4)-ethylene-dihydroxy thiophene (PEDOT), metal nano wire, carbon nanotube, graphene, or the like.

The third touch insulating layer 450 may be disposed on the second conductive layer 440. The third touch insulating layer 450 may include an inorganic or organic material. In an example in which the third touch insulating layer 450 is an inorganic material, the third touch insulating layer 450 may include at least one material selected from a group including SiNₓ, AlNₓ, ZrNₓ, TiNₓ, HfNₓ, TaNₓ, SiOₓ, AlOₓ, TiOₓ, SnOₓ, CeOₓ, and SiON. In an example in which the third touch insulating layer 450 is an organic material, the third touch insulating layer 450 may include at least one material selected from a group including acrylic resin, methacrylic resin, polyisoprene, vinyl resin, epoxy resin, urethane resin, cellulosic resin, and perylene resin.

The optical functional layer 500 may be disposed on the touch layer 400. Although not illustrated in FIG. 2, the optical functional layer 500 may include a light-shielding layer (not shown) capable of reflecting external light. The optical functional layer 500 may include a color filter arranged correspondingly to an emission area of each subpixel. For example, the optical functional layer 500 may include color filters (not shown) corresponding to the first to third emission areas EA1, EA2, and EA3.

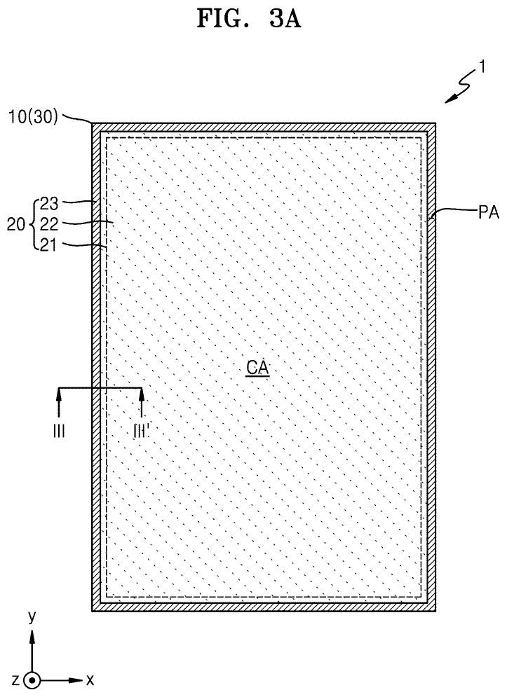

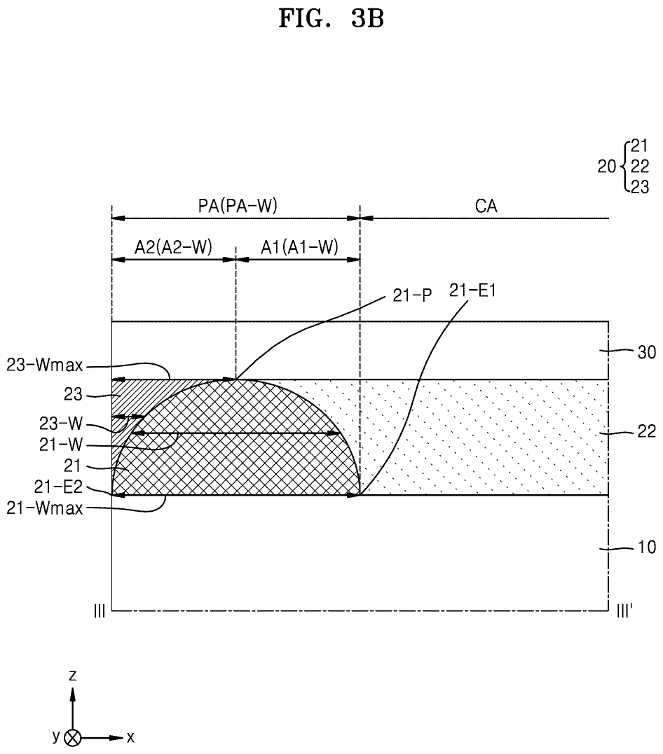

FIG. 3A is a schematic plan view of a display apparatus 1 according to an embodiment.

Referring to FIG. 3A, the display apparatus 1 may include the display panel 10, an adhesive layer 20, and a window 30.

The adhesive layer 20 may include the first to third adhesive layers 21, 22, and 23 (hereinafter, also referred to as the first adhesive layer 21, the second adhesive layer 22, and the third adhesive layer 23). The first to third adhesive layers 21, 22, and 23 may each include an optical transparent adhesive. For example, the first to third adhesive layers 21, 22, and 23 may include optically clear resin (OCR). In an embodiment, the first to third adhesive layers 21, 22, and 23 may include the same material.

The first adhesive layer 21 may be disposed on the display panel 10 correspondingly to the peripheral area PA. The first adhesive layer 21 may have an approximate frame shape surrounding the central area CA.

The second adhesive layer 22 may be disposed on the display panel 10 correspondingly to the central area CA. A portion of the second adhesive layer 22 may overlap the peripheral area PA and the first adhesive layer 21. An area in which the second adhesive layer 22 overlaps the first adhesive layer 21 may have an approximate frame shape surrounding the central area CA.

The third adhesive layer 23 may be disposed on the display panel 10 correspondingly to the peripheral area PA. The third adhesive layer 23 may overlap the first adhesive layer 21. An external edge of the third adhesive layer 23 may overlap an edge of the display panel 10. A width of the third adhesive layer 23 may be less than a width of the first adhesive layer 21. The third adhesive layer 23 may have an approximate frame shape surrounding the central area CA and/or the second adhesive layer 22.

The second adhesive layer 22 and the third adhesive layer 23 may cover the upper surface of the first adhesive layer 21. In an embodiment, the entire upper surface of the first adhesive layer 21 may be covered by the second adhesive layer 22 and the third adhesive layer 23.

FIG. 3B is a schematic cross-sectional view of a portion of the display apparatus 1 taken along line III-III′ of FIG. 3A, according to an embodiment.

Referring to FIG. 3B, the adhesive layer 20 may be arranged between the display panel 10 and the window 30. For example, the adhesive layer 20 may be disposed on the upper surface of the display panel, and the window 30 may be disposed on the upper surface of the adhesive layer 20.

The adhesive layer 20 may include the first to third adhesive layers 21, 22, and 23.

The first adhesive layer 21 may be disposed on the upper surface of the display panel 10 in the peripheral area PA.

From a cross-sectional view (e.g., from the +y or −y direction), a width 21-W of the first adhesive layer 21 may be variable (e.g., may not be constant). In an embodiment, the width 21-W of the first adhesive layer 21 may change along the ±z direction. For example, the first adhesive layer 21 may have a substantially semicircular shape of which the lower surface contacting the display panel 10 is the peak width 21-Wmax of the first adhesive layer 21 and the width 21-W decreases along the +z direction. Embodiments of the present disclosure are not limited thereto, and the cross-sectional shape of the first adhesive layer 21 may be variously modified.

In an embodiment, the first adhesive layer 21 may cover the entire peripheral area PA. For example, the width or the peak width 21-Wmax of the lower surface of the first adhesive layer 21 may be equal to a width PA-W of the peripheral area PA.

A thickness of the first adhesive layer 21 may be variable (e.g., may not be constant). For example, the thickness of the first adhesive layer 21 may change along the ±x direction. A portion where the thickness of the first adhesive layer 21 is greatest may be defined as a peak 21-P of the first adhesive layer 21. Among the edges of the first adhesive layer 21, the edge adjacent to the central area CA may be defined as a first edge 21-E1. An edge located on the opposite side of the first edge 21-E1 among the edges of the first adhesive layer 21 may be defined as a second edge 21-E2. In this case, a portion of the first adhesive layer 21 arranged between the peak 21-P and the first edge 21-E1 may be understood as a first portion A1, and a portion of the first adhesive layer 21 arranged between the peak 21-P and the second edge 21-E2 may be understood as a second portion A2. In an embodiment, the cross-sectional shape of the first adhesive layer 21 may be substantially semicircular and a width A1-W of the first portion A1 may be substantially equal to a width A2-W of the second portion A2.

The second adhesive layer 22 may be disposed on the display panel 10 correspondingly to the central area CA.

A portion of the second adhesive layer 22 may extend to the peripheral area PA. In an embodiment, an edge of the second adhesive layer 22 may be in contact with the first edge 21-E1 of the first adhesive layer 21, and another edge of the second adhesive layer 22 may be in contact with the peak 21-P of the first adhesive layer 21.

The second adhesive layer 22 may overlap the first portion A1 of the first adhesive layer 21 in the peripheral area PA. For example, the second adhesive layer 22 may cover at least a portion of the first portion A1 of the first adhesive layer 21. In other words, for example, a space between the first adhesive layer 21 (or the first portion A1) and the window 30 may be at least partially filled by the second adhesive layer 22 in an area of the first adhesive layer 21 overlapping the first portion A1 of the first adhesive layer 21. Thus, the thickness of the second adhesive layer 22 is not constant and may change along the ±x direction in an area overlapping the first portion A1 of the first adhesive layer

The second adhesive layer 22 may directly contact the first portion A1 of the first adhesive layer 21. For example, the second adhesive layer 22 may cover at least a portion of the first portion A1 while being in direct contact with the upper surface of the first portion A1 of the first adhesive layer 21.

The third adhesive layer 23 may be disposed on the display panel 10 in the peripheral area PA. For example, the third adhesive layer 23 may be disposed on the first adhesive layer 21 in the peripheral area PA.

The third adhesive layer 23 may overlap a portion of the upper surface of the first adhesive layer 21. For example, an edge of the third adhesive layer 23 may be in contact with the second edge 21-E2 (or the edge of the display panel 10) of the first adhesive layer 21, and another edge of the third adhesive layer 23 may be in contact with the peak 21-P of the first adhesive layer 21.

The third adhesive layer 23 may overlap the second portion A2 of the first adhesive layer 21 in the peripheral area PA. For example, the third adhesive layer 23 may cover at least a portion of the second portion A2 of the first adhesive layer 21. In other words, for example, a space between the first adhesive layer 21 (or the second portion A2) and the window 30 may be at least partially filled by the third adhesive layer 23 in an area of the first adhesive layer 21 overlapping the second portion A2 of the first adhesive layer 21. Thus, the thickness of the third adhesive layer 21 is not constant and may change along the ±x direction.

In some aspects, a width 23-W of the third adhesive layer 23 is not constant and may change along the ±z direction. For example, the width 23-W of the third adhesive layer 23 may be a peak width 23-Wmax in the upper surface contacting the window 30 and may be reduced along the −z direction. The peak width 23-Wmax of the third adhesive layer 23 may be equal to or less than the width A2-W of the second portion A2 of the first adhesive layer 21.

The third adhesive layer 23 may directly contact the second portion A2 of the first adhesive layer 21. For example, the third adhesive layer 23 may directly contact the upper surface of the second portion A2 of the first adhesive layer 21 and cover at least a portion of the second portion A2.

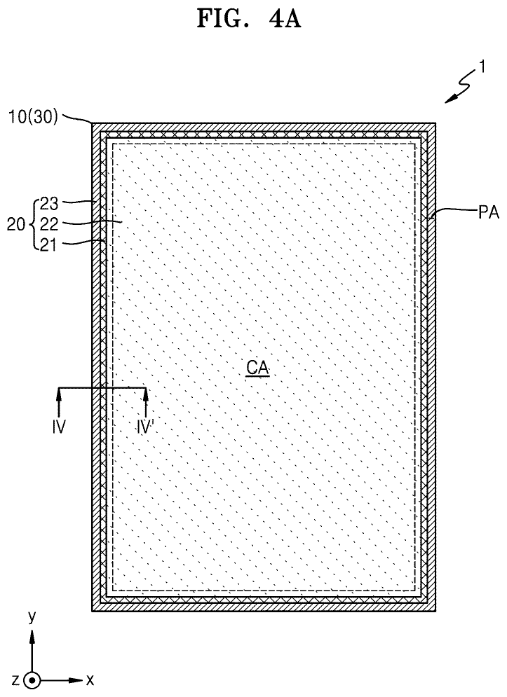

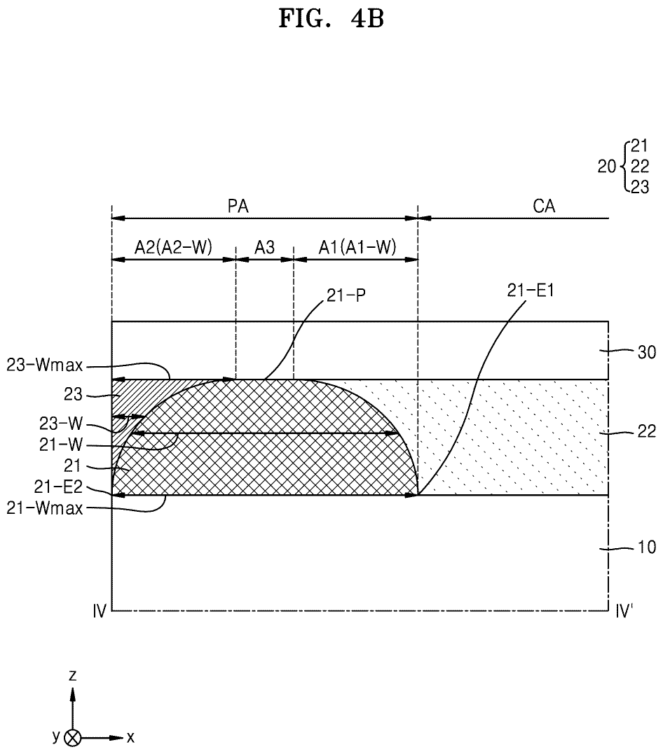

The second adhesive layer 22 and the third adhesive layer 23 may cover the entire upper surface of the first adhesive layer 21. For example, the second adhesive layer 22 and the third adhesive layer 23 may cover the upper surfaces of the first part A1 and the second part A2 of the first adhesive layer 21, respectively, and may contact each other at the peak 21-P of the first adhesive layer 21. Embodiments of the present disclosure are not limited thereto, and, in some embodiments, the second adhesive layer 22 and the third adhesive layer 23 may cover portions of the first portion A1 and the second portion A2 of the first adhesive layer 21, respectively. In this case, a portion of the first adhesive layer 21 may be exposed. For example, the first adhesive layer 21 may not be covered by the second adhesive layer 22 or the third adhesive layer 23 in an area adjacent to the peak 21-P of the first adhesive layer 21. Such an embodiment is described above with reference to FIGS. 4A and 4B.

FIG. 4A is a schematic plan view of a display apparatus according to an embodiment.

Referring to FIG. 4A, a portion of the first adhesive layer 21 may not be covered by the second adhesive layer 22 and the third adhesive layer 23. The portion of the first adhesive layer 21 which is not covered by the second adhesive layer 22 and the third adhesive layer 23 may be disposed between the second adhesive layer 22 and the third adhesive layer 23. The portion of the first adhesive layers 21 not covered by the second adhesive layer 22 and the third adhesive layer 23 may have an approximate frame shape surrounding the central area CA.

FIG. 4B is a schematic cross-sectional view of a portion of the display apparatus taken along line IV-IV′ of FIG. 4A, according to some embodiments.

Referring to FIG. 4B, the first adhesive layer 21 may include a third portion A3 arranged between the first portion A1 and the second portion A2. The third portion A3 may not be covered by the second adhesive layer 22 and third adhesive layer 23. Thus, the third portion A3 of the first adhesive layer 21 may directly contact the window 30.

The third portion A3 of the first adhesive layer 21 may have a constant thickness. The thickest portion of the first adhesive layer 21 may be an area, not a point. For example, the third portion A3 may be the thickest portion of the first adhesive layer 21, and the peak 21-P of the first adhesive layer 21 may be any point on the third portion A3. Alternatively, the peak 21-P of the first adhesive layer 21 may be defined as an upper surface of the third portion A3. Accordingly, for example, both sides (e.g., the first portion A1 and the second portion A2) of the first adhesive layer 21 may be an arc shape and the first adhesive layer 21 may have an approximate plateau shape of which the upper surface (e.g., the third portion A3) is flat.

The second adhesive layer 22 and the third adhesive layer 23 may cover the upper surfaces of the first part A1 and the second part A2 of the first adhesive layer 21, respectively, and may contact each other through the third portion A3 of the first adhesive layer 21.

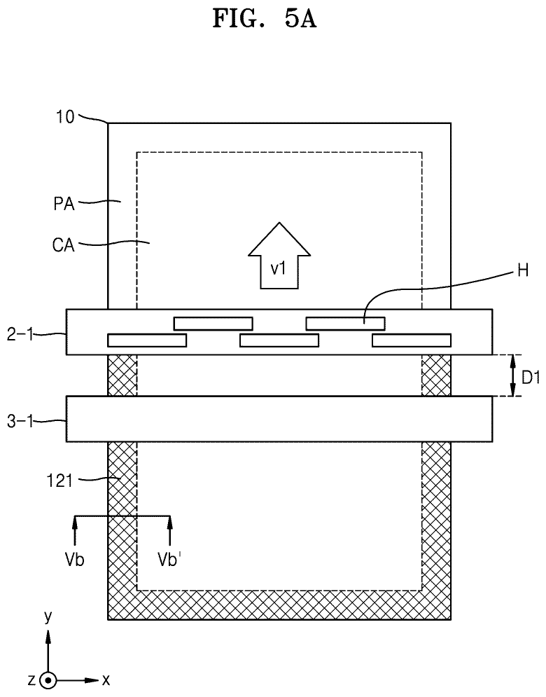

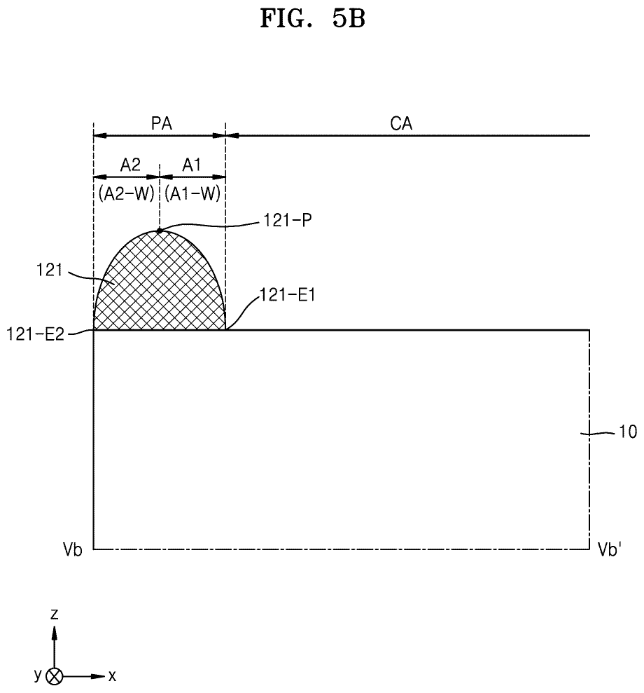

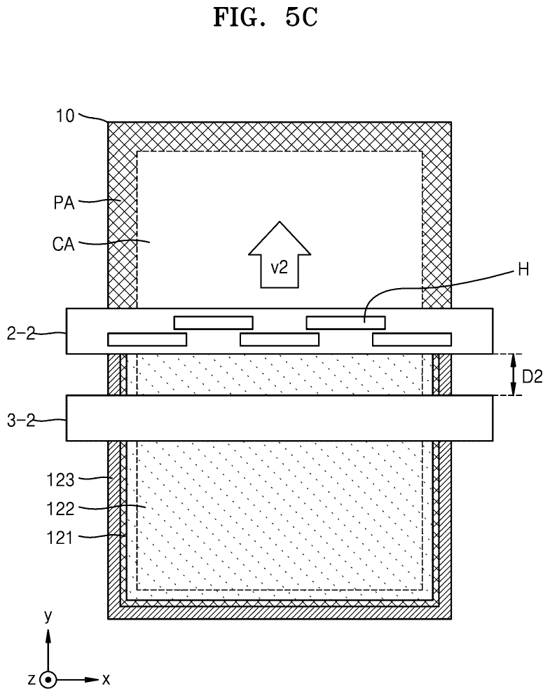

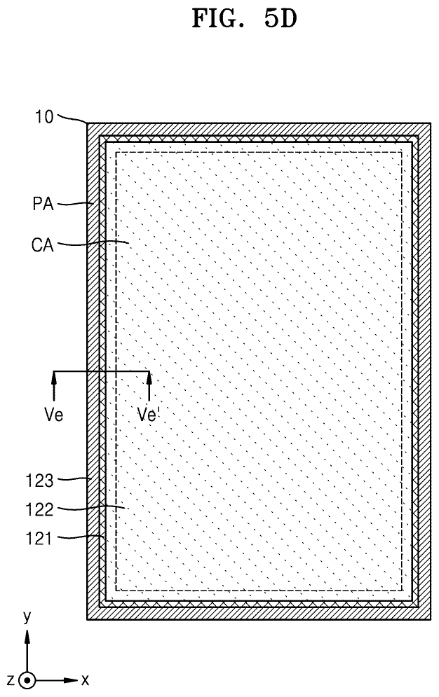

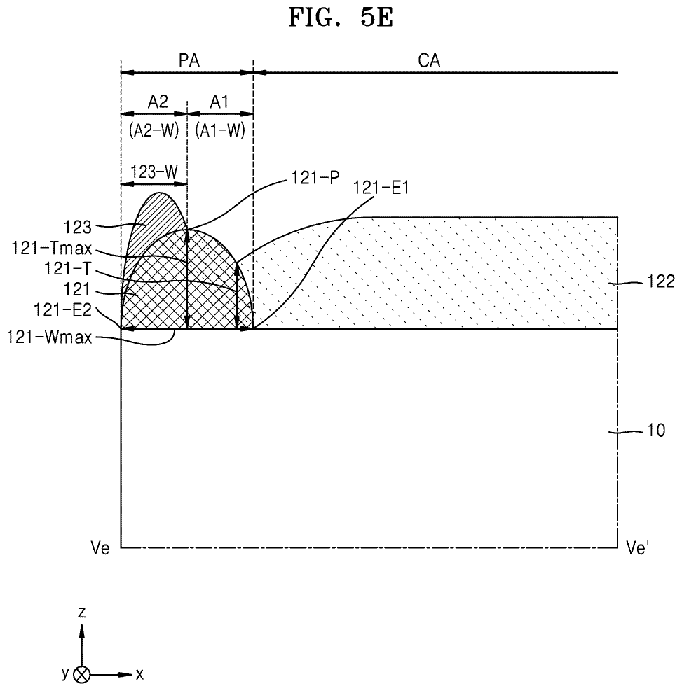

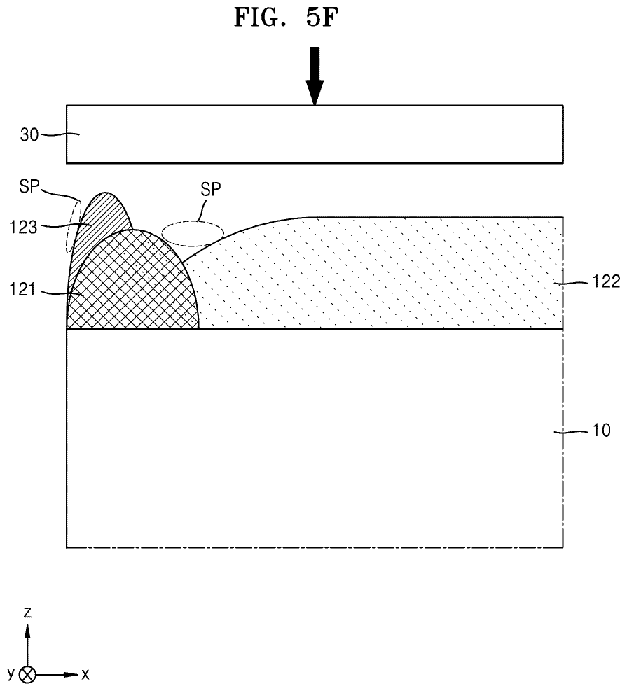

FIGS. 5A, 5C, and 5D are each a plan view of a display apparatus in a processing state of a method of manufacturing the display apparatus according to an embodiment.

FIGS. 5B, 5E, and 5F are each a cross-sectional view of a display apparatus in a processing state of a method of manufacturing the display apparatus according to an embodiment. The terms method and process may be used interchangeably herein.

FIGS. 5A and 5B are a plan view and a cross-sectional view of the display apparatus, respectively, according to a process of forming the first adhesive material layer 121. FIGS. 50, 5D, and 5E are each a plan view or a cross-sectional view of the display apparatus, according to a process of forming the second adhesive material layer 122 and the third adhesive material layer 123. FIG. 5F is a cross-sectional view of the display apparatus according to a process of pressing the window 30. Hereinafter, in the examples, the first adhesive material layer 121, the second adhesive material layer 122, and the third adhesive material layer 123 may include the same material.

Referring to FIG. 5A, the process may include forming the first adhesive material layer 121 on the display panel 10.

The process of forming the first adhesive material layer 121 may include applying an adhesive material through a first injection apparatus 2-1 and semi-hardening through a first hardening apparatus 3-1.

First, the process may include applying the adhesive material (e.g., OCR) included in the first adhesive material layer 121 to the display panel 10 by using the first injection apparatus 2-1.

The first injection apparatus 2-1 may be an inkjet injection apparatus including a plurality of heads H. The first injection apparatus 2-1 may include a nozzle (not shown) to inject the adhesive material, a storage unit (not shown) to store the adhesive material, and a pump (not shown) to supply the adhesive material to the nozzle.

The process may include controlling the first injection apparatus 2-1 such that the adhesive material is injected from predetermined heads H for the first adhesive material layer 121 to be correspondingly applied to the peripheral area PA of the display panel 10, without being injected from other heads H. For example, the process may include controlling some of the heads H (e.g., not all of the heads H) of the first injection apparatus 2-1 overlapping the peripheral area PA to inject the adhesive material such that the first adhesive material layer 121 is applied to the peripheral area PA.

The process may include moving the first injection apparatus 2-1 in a direction at a certain speed and injecting the adhesive material using the first injection apparatus 2-1. For example, the first injection apparatus 2-1 may move in the +y direction by a first speed v1 and inject the adhesive material. In this case, the process may include appropriately controlling the injection amount per second by the first injection apparatus 2-1 and controlling the first speed v1 such that the first adhesive material layer 121 is entirely applied with a constant thickness.

The adhesive material applied by the first injection apparatus 2-1 may be in a liquid state having a certain viscosity. If the adhesive material is left in the above state, the adhesive material move to the outside of the display panel or to the central area CA.

To prevent such a case (e.g., unintentional or undesired movement of the adhesive material), the process may include performing semi-hardening of adhesive materials. For example, the process may include performing semi-hardening of the first adhesive material layer 121 after (e.g., right after) applying the first adhesive material layer 121 by injecting the adhesive material by using the first injection apparatus 2-1.

The process may include emitting light of a predetermined wavelength band using the first hardening apparatus 3-1 may irradiate. For example, the first hardening apparatus 3-1 may emit light (e.g., ultraviolet light) of a wavelength band that can cure or harden the adhesive material injected by the first injection apparatus 2-1. Descriptions herein of emitting light of a wavelength band include irradiating an object (e.g., first adhesive material layer 121, other adhesive material layers, and the like) with the light of the wavelength band.

The process may include controlling the first hardening apparatus 3-1 and the first injection apparatus 2-1 such that the first hardening apparatus 3-1 follows behind the first injection apparatus 2-1 in the same direction as the first injection apparatus 2-1. In an embodiment, the process may include moving the first injection apparatus 2-1 and the first hardening apparatus 3-1 in the +y direction, and the first hardening apparatus 3-1 may be apart from the first injection apparatus 2-1 by a first distance D1 in the −y direction (e.g., during the movement and emission of light by the first injection apparatus 2-1 and the first hardening apparatus 3-1). The movement speed of the first injection apparatus 2-1 and the first hardening apparatus 3-1 may be equal to the first speed v1. Thus, for example, the first injection apparatus 2-1 and the first hardening apparatus 3-1 may be apart from each other by a first distance D1, and both may move in the +y direction at a first speed v1.

The process may include controlling the first hardening apparatus 3-1 in association with controlling the amount of light incident on the first adhesive material layer 121. The amount of emitted light incident on the first adhesive material layer 121 may be controlled in the first hardening apparatus 3-1. For example, the process may include controlling the first speed v1 such that the first adhesive material layer 121 is not completely hardened (e.g., is semi-hardened) while having a certain elastic modulus. In an example of the process, the intensity of light emitted from the first hardening apparatus 3-1 (and the corresponding intensity of the light at the first adhesive material layer 121) may be controlled according to the first speed v1 such that the first adhesive material layer 121 is not completely hardened and is semi-hardened while having a certain elastic modulus. The first adhesive material layer 121, which is semi-hardened by irradiating the first adhesive material layer 121 with light by using the first hardening apparatus 3-1, may have a certain elastic modulus and may maintain a certain shape. In an example, based on the semi-hardening, the first adhesive material layer 121 may maintain the shape until a subsequent process.

FIG. 5B is a cross-sectional view of the display apparatus taken along line Vb-Vb′ of FIG. 5A.

Referring to FIG. 5B, the process may include disposing the first adhesive material layer 121 on the display panel 10 and semi-hardening the first adhesive material layer 121 such that the first adhesive material layer 121 maintains a certain shape. The process may include arranging the first adhesive material layer 121 correspondingly to the peripheral area PA.

The thickness of the first adhesive material layer 121 may be variable (e.g., may not be constant). For example, the thickness of the first adhesive material layer 121 may change along the ±x direction. A portion where the thickness of the first adhesive material layer 121 is greatest may be defined as a peak 121-P of the first adhesive material layer 121. Among the edges of the first adhesive material layer 121, the edge adjacent to the central area CA may be defined as a first edge 121-E1. An edge located on the opposite side of the first edge 121-E1 among the edges of the first adhesive material layer 121 may be defined as a second edge 121-E2. In this case, a portion of the first adhesive material layer 121 arranged between the peak 121-P and the first edge 121-E1 may be referred to as the first portion A1, and a portion of the first adhesive material layer 121 arranged between the peak 121-P and the second edge 121-E2 may be referred to as the second portion A2. In an embodiment, the cross-sectional shape of the first adhesive material layer 21 may be substantially semi-oval and the width A1-W of the first portion A1 may be substantially equal to the width A2-W of the second portion A2.

Referring to FIG. 5C, the process may include forming the second adhesive material layer 122 and the third adhesive material layer 123 on the display panel 10 described with reference to the embodiment illustrated in FIG. 5A.

The process of forming the second adhesive material layer 122 and the third adhesive material layer 123 may include applying the adhesive material through a second injection apparatus 2-2 and semi-hardening through a second hardening apparatus 3-2.

First, the process may include applying the adhesive material included in the second adhesive material layer 122 and the third adhesive material layer 123 to the display panel 10 of the embodiment illustrated in FIG. 5A by using the second injection apparatus 2-2. In an embodiment, the adhesive material included in the second adhesive material layer 122 and the third adhesive material layer 123 may be the same adhesive material (e.g., OCR) as the material included in the first adhesive material layer 121. In an embodiment, the process may include simultaneously applying the second adhesive material layer 122 and applying the third adhesive material layer 123.

Similarly to the process of applying the first adhesive material layer 121, the process may include applying the second adhesive material layer 122 and the third adhesive material layer 123 according to a desired shape by controlling the heads H of the second injection apparatus 2-2. For example, the process may include controlling the second injection apparatus 2-2 such that the heads H of the second injection apparatus 2-2 inject the adhesive material correspondingly to the central area CA to apply the second adhesive material layer 122, and such that the adhesive material is injected correspondingly to the peripheral area PA to apply the third adhesive material layer 123. In this case, the process may include controlling the second injection apparatus 2-2 such that the adhesive substance is prevented from being injected by (e.g., is not injected from) a certain portion of the heads H, thereby separating the second adhesive material layer 122 and the third adhesive material layer 123 from each other.

The process may include moving the second injection apparatus 2-2 in a direction at a certain speed and injecting the adhesive material using the second injection apparatus 2-2. For example, the second injection apparatus 2-2 may move in the +y direction by a second speed v2 and inject the adhesive material. In this case, the process may include appropriately controlling the injection amount per second by the second injection apparatus 2-2 and the second speed v2 such that the second adhesive material layer 122 and the third adhesive material layer 123 are entirely applied with a constant thickness. In some embodiments, the second speed v2 may be equal to the first speed v1 (FIG. 5A). In some other embodiments the second speed v2 may be different from the first speed v1.

Similarly to the process of semi-hardening the first adhesive material layer 121, the process may include semi-hardening the second adhesive material layer 122 and the third adhesive material layer 123. For example, the process may include semi-hardening the second adhesive material layer 122 and the third adhesive material layer 123 after (e.g., immediately after, after one or more intervening operations) applying the second adhesive material layer 122 and the third adhesive material layer 123 by injecting the adhesive material by using the second injection apparatus 2-2.

The process may include emitting light of a predetermined wavelength band using the second hardening apparatus 3-2. For example, the second hardening apparatus 3-2 may emit light (e.g., ultraviolet light) of a wavelength band that can cure or harden the adhesive material injected by the second injection apparatus 2-2.

The second hardening apparatus 3-2 may follow behind the second injection apparatus 2-2 in the same direction as the second injection apparatus 2-2. In an embodiment, the second injection apparatus 2-2 and the second hardening apparatus 3-2 may move in the +y direction. The second hardening apparatus 3-2 may be apart from the second injection apparatus 2-2 by a second distance D2 in the −y direction. The movement speed of the second injection apparatus 2-2 and the second hardening apparatus 3-2 may be equal to the second speed v2. Thus, the second injection apparatus 2-2 and the second hardening apparatus 3-2 may be apart from each other by the second distance D2, and both may move in the +y direction at the second speed v2. In some embodiments, the second distance D2 may be different from the first distance D1 (FIG. 5A). For example, the second distance D2 may be less than the first distance D1 (FIG. 5A).

The process may include controlling the second hardening apparatus 3-2 in association with controlling the amount of light incident on the second adhesive material layer 122. The amount of emitted light incident on the second adhesive material layer 122 and the third adhesive material layer 123 may be controlled in the second hardening apparatus 3-2. For example, the process may include controlling the second speed v2 such that the second adhesive material layer 122 and the third adhesive material layer 123 are not completely hardened (e.g., are semi-hardened) while having a certain elastic modulus. In an example of the process, the intensity of light emitted (and the corresponding intensity of the light at the second adhesive material layer 122 and the third adhesive material layer 123) from the second hardening apparatus 3-2 may be controlled according to the second speed v2 such that the second adhesive material layer 122 and the third adhesive material layer 123 are not completely hardened and are semi-hardened while having a certain elastic modulus. The second adhesive material layer 122 and the third adhesive material layer 123, which are semi-hardened by irradiating the second adhesive material layer 122 with light by using the second hardening apparatus 3-2, may have a certain elastic modulus and may maintain a certain shape. In an example, based on the semi-hardening, the second adhesive material layer 122 and the third adhesive material layer 123 may maintain the shape until a subsequent process.

In the process of emitting light by using the second hardening apparatus 3-2, the process may include exposing the second adhesive material layer 122 and the third adhesive material layer 123 to light emitted by the second hardening apparatus 3-2, and further, exposing the first adhesive material layer 121 to the light irradiated by the second hardening apparatus 3-2. Thus, the first adhesive material layer 121 may show an effect of having been semi-hardened twice. The elastic modulus of the first adhesive material layer 121 may be different from the elastic modulus of the second adhesive material layer 122 and the third adhesive material layer 123.

Referring to FIG. 5D, the process may include disposing the first adhesive material layer 121, the second adhesive material layer 122, and the third adhesive material layer 123 on the display panel 10.

The process may include semi-hardening the first adhesive material layer 121, the second adhesive material layer 122, and the third adhesive material layer 123 such that each maintains a certain shape. The process may include disposing and semi-hardening the first adhesive material layer 121 and the third adhesive material layer 123 such that the first adhesive material layer 121 and the third adhesive material layer 123 correspond to the peripheral area PA and have a frame shape surrounding the central area CA. The process may include arranging the second adhesive material layer 122 correspondingly to the central area CA such that the second adhesive material layer 122 covers the central area CA. The second adhesive material layer 122 and the third adhesive material layer 123 may be apart from each other, and a portion of the first adhesive material layer 121 may be exposed in an area wherein the second adhesive material layer 122 and the third adhesive material layer 123 are apart from each other.

FIG. 5E is a cross-sectional view of the display apparatus of FIG. 5D, taken along line Ve-Ve′ of FIG. 5D.

Referring to FIG. 5E, the process may include disposing and semi-hardening the first adhesive material layer 121, the second adhesive material layer 122, and the third adhesive material layer 123 on the display panel 10 while maintaining a certain shape for each of the first adhesive material layer 121, the second adhesive material layer 122, and the third adhesive material layer 123.

The characteristics of the first adhesive material layer 121 may be the same as described with reference to FIG. 5B.

The process may include disposing the second adhesive material layer 122 on the display panel 10 correspondingly to the central area CA.

A portion of the second adhesive material layer 122 may extend to the peripheral area PA. In an embodiment, an edge of the second adhesive material layer 122 may be in contact with the first edge 121-E1 of the first adhesive material layer 121, and another edge of the second adhesive material layer 122 may be in arranged on the first portion A1 of the first adhesive material layer 121.

The second adhesive material layer 123 may overlap the first portion A1 of the first adhesive material layer 121 in the peripheral area PA. For example, the second adhesive material layer 122 may cover a portion of the first portion A1 of the first adhesive material layer 121.

The second adhesive material layer 122 may directly contact the first portion A1 of the first adhesive material layer 121. For example, the second adhesive material layer 122 may cover a portion of the first portion A1 while being in direct contact with the upper surface of the first portion A1 of the first adhesive material layer 121.

A thickness 121-T of the first adhesive material layer 121 (or the first portion A1) covered by the second adhesive material layer 122 may be less than a peak thickness 121-Tmax of the first adhesive material layer 121. Accordingly, the first adhesive material layer 121 may act as a dam that prevents the second adhesive material layer 122 from overflowing beyond the peripheral area PA to the edge of the display panel 10.

The process may include disposing the third adhesive material layer 123 on the display panel 10 in the peripheral area PA. For example, the third adhesive material layer 123 may be disposed on the first adhesive material layer 121 in the peripheral area PA.

The third adhesive material layer 123 may overlap a portion of the upper surface of the first adhesive material layer 121. In an embodiment, an edge of the third adhesive material layer 123 may contact the second edge 121-E2 of the first adhesive material layer 121 (or the edge of the display panel 10) and another edge of the third adhesive material layer 123 may contact the peak 121-P of the first adhesive material layer 121. In some embodiments, another edge of the third adhesive material layer 123 may be arranged on the second portion A2 of the first adhesive material layer 121.

The third adhesive material layer 123 may overlap the second portion A2 of the first adhesive material layer 121 in the peripheral area PA. For example, the third adhesive material layer 123 may cover a portion of the second portion A2 of the first adhesive material layer 121. In an embodiment, a width 123-W of the third adhesive material layer 123 measured from an edge of the third adhesive material layer 123 to another edge of the third adhesive material layer 123 along a direction (e.g., the ±x direction) parallel to the upper surface of the display panel 10 may be equal to or less than the width A2-W of the second portion A2.

The third adhesive material layer 123 may directly contact the second portion A2 of the first adhesive material layer 121. For example, the third adhesive material layer 123 may directly contact the upper surface of the second portion A2 of the first adhesive material layer 121 and cover at least a portion of the second portion A2.

The second adhesive material layer 122 and the third adhesive material layer 123 may be apart from each other. A portion of the first adhesive material layer 121 may be exposed in an area in which the second adhesive material layer 122 and the third adhesive material layer 123 are apart from each other. In the example of FIG. 5E, the width 123-W of the third adhesive material layer 123 is identical to the width A2-W of the second portion A2, and the portion of the third adhesive material layer 123 in which the second adhesive material layer 122 is apart from the third adhesive material layer 123 is arranged only in the first portion A1 of the first adhesive material layer 121, but embodiments are not limited thereto. In some embodiments, the width 123-W of the third adhesive material layer 123 may be less than the width A2-W of the second portion A2, and an area in which the second adhesive material layer 122 is apart from the third adhesive material layer 123 may be arranged in the first portion A1 and second portion A2 of the first adhesive material layer 121.

Referring to FIG. 5F, the process may include disposing the window 30 on the first adhesive material layer 121, the second adhesive material layer 122, and the third adhesive material layer 123 described with reference to the embodiment shown in FIG. 5E. The first adhesive material layer 121, the second adhesive material layer 122, and the third adhesive material layer 123 may act as adhesives that attach the display panel 10 to the window 30.

First, the process may include moving the window 30 from the +z direction to the −z direction with respect to the first adhesive material layer 121, the second adhesive material layer 122, and the third adhesive material layer 123. In this case, the upper surface of the display panel 10 and the lower surface of the window 30 may be parallel to each other. For example, the process may include arranging the display panel 10 and the window 30 such that the upper surface of the display panel 10 and the lower surface of the window 30 are parallel to the +x direction and the −x direction.

After moving the window 30 in the −z direction such that the window 30 contacts the upper surface of the third adhesive material layer 123, the process may include applying pressure (e.g., continuously applying pressure) in the −z direction. Since the third adhesive material layer 123 is semi-hardened, which is a state that is not completely hardened, the pressure applied in the −z direction may deform the form of the third adhesive material layer 123. In this case, the third adhesive material layer 123 pressed by the window 30 may be deformed and may fill the space SP between the third adhesive material layer 123 and the edge of the display panel 10.

In an example, the process may include then continuing to apply the pressure in the-z direction, and accordingly, the lower surface of the window 30 may be in contact with the upper surface of the second adhesive material layer 122. The process may include continuing to apply the pressure. Since the second adhesive material layer 122 is semi-hardened, which is a state that is not completely hardened, the continued pressure applied in the −z direction may deform the form of the second adhesive material layer 122. Therefore, the second adhesive material layer 122 may be deformed to fill the space SP between the first adhesive material layer 121 and the second adhesive material layer 122.

By applying pressure in the −z direction, the process may modify the second adhesive material layer 122 and the third adhesive material layer 123 such that the second adhesive material layer 122 and the third adhesive material layer 123 fill the entire space SP, thereby completely hardening the first adhesive material layer 121, the second adhesive material layer 122, and the third adhesive material layer 123. The process of completely hardening the first adhesive material layer 121, the second adhesive material layer 122, and the third adhesive material layer 123 may include emitting light (e.g., ultraviolet light) for a certain period of time. Accordingly, the process may completely harden the first adhesive material layer 121, the second adhesive material layer 122, and the third adhesive material layer 123 and attach (e.g., due to the hardening) the display panel 10 to the window 30.

Through the above-described process, the display apparatus according to an embodiment illustrated in FIGS. 3A and 3B may be manufactured. In this case, the completely hardened first adhesive material layer 121, second adhesive material layer 122, and third adhesive material layer 123 may respectively correspond to the first adhesive layer 21, the second adhesive layer 22, and the third adhesive layer 23 (FIG. 3B).

In some embodiments, the process may include additionally applying pressure in the −z direction before completely hardening the first adhesive material layer 121, the second adhesive material layer 122, and the third adhesive material layer 123. In this case, for example, the pressure in the −z direction may further modify one or more characteristics of the first adhesive material layer 121. For example, the pressure in the −z direction may reduce the thickness (or length in the ±z direction) of the first adhesive material layer 121 and increase the width (or length in the ±x direction) of the first adhesive material layer 121. In some cases, the pressure in the −z direction may result in a portion of the upper surface of the first adhesive material layer 121 directly contacting the window 30. Through the above-described process, the display apparatus according to an embodiment illustrated in FIGS. 4A and 4B may be manufactured. In this case, the modified and completely hardened first adhesive material layer 121, second adhesive material layer 122, and third adhesive material layer 123 may respectively correspond to the first adhesive layer, the second adhesive layer, and the third adhesive layer 23 (FIG. 4B).

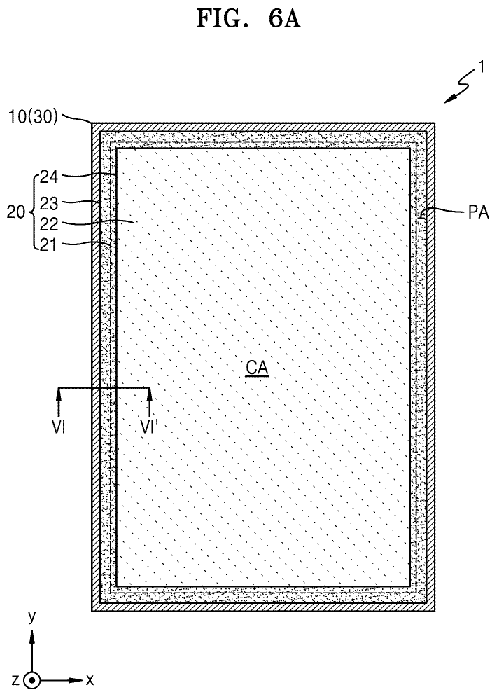

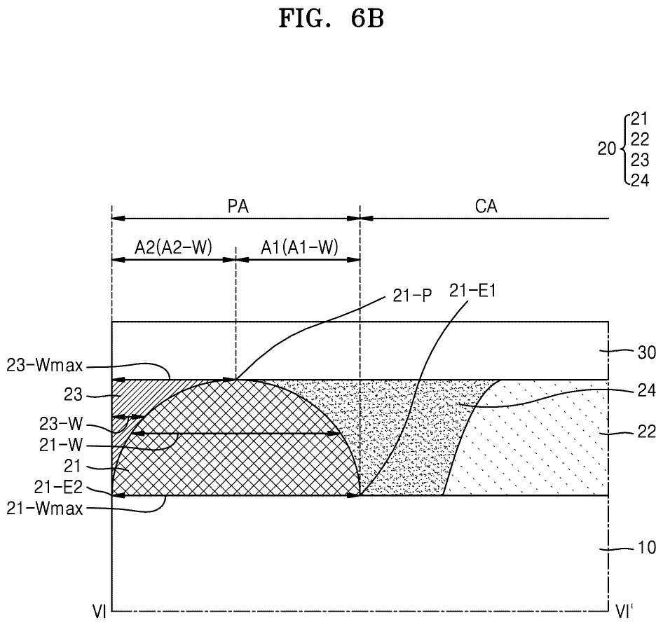

FIG. 6A is a schematic plan view of a display apparatus 1 according to an embodiment.

Referring to FIG. 6A, the adhesive layer 20 may include the first adhesive layer 21, the second adhesive layer 22, the third adhesive layer 23, and a fourth adhesive layer 24. In an embodiment, the first adhesive layer 21, the second adhesive layer 22, the third adhesive layer 23, and the fourth adhesive layer 24 may include the same material. The embodiment described with reference to FIG. 6A may include aspects of other embodiments described herein, and repeated descriptions of like elements are omitted for brevity.

The fourth adhesive layer 24 may overlap each of a portion of the first adhesive layer 21 and a portion of the second adhesive layer 22. The fourth adhesive layer 24 may overlap each of a portion of the central area CA and a portion of the peripheral area PA. The fourth adhesive layer 24 may have an approximate frame shape surrounding the central area CA.

FIG. 6B is a schematic cross-sectional view of a portion of the display apparatus 1 taken along line VI-VI′ of FIG. 6A, according to some embodiments.

Referring to FIG. 6B, the adhesive layer 20 may include the first adhesive layer 21, the second adhesive layer 22, the third adhesive layer 23, and the fourth adhesive layer 24.

The characteristics of the first adhesive layer 21 and the third adhesive layer 23 are the same as described with reference to FIG. 3B.

The second adhesive layer 22 may be arranged correspondingly to the central area CA. In an embodiment, the second adhesive layer 22 may be arranged in the central area CA. The first adhesive layer 21 and the second adhesive layer 22 may be apart from each other.

The fourth adhesive layer 24 may be arranged between the first adhesive layer 21 and the second adhesive layer 22. For example, the fourth adhesive layer 24 may be arranged between the display panel 10 and the window 30 and fill a space wherein the first adhesive layer 21 and the second adhesive layer 22 are apart from each other.

Therefore, the width of the fourth adhesive layer 24 may be variable (e.g., may not be constant). In an embodiment, the width of the fourth adhesive layer 24 may be the greatest in an upper surface of the fourth adhesive layer 24 directly contacting the window 30 and may be decreased along the −z direction.

The fourth adhesive layer 24 may overlap the central area CA and the peripheral area PA. In an embodiment, a portion of the fourth adhesive layer 24 may overlap the first adhesive layer 21 in the peripheral area PA. A portion of the fourth adhesive layer 24 may overlap the second adhesive layer 22 in the central area CA.

The fourth adhesive layer 24 may directly contact the first adhesive layer 21, the second adhesive layer 22, and the display panel 10. In an embodiment, a portion of the fourth adhesive layer 24 may directly contact the first adhesive layer 21 and cover a portion of the first adhesive layer 21 in the peripheral area PA. A portion of the fourth adhesive layer 24 may directly contact the second adhesive layer 22 and cover a portion of the second adhesive layer 22 in the central area CA. The fourth adhesive layer 24 may directly contact the display panel 10 in an area wherein the first adhesive layer 21 and the second adhesive layer 22 are apart from each other in the central area CA.

The third adhesive layer 23 and the fourth adhesive layer 24 may cover the entire upper surface of the first adhesive layer 21. For example, the third adhesive layer 23 covers the upper surface of the second portion A2 of the first adhesive layer 21, the fourth adhesive layer 24 covers the upper surface of the first portion A1 of the first adhesive layer 21, and the third adhesive layer 23 and the fourth adhesive layer 24 may contact each other in the peak 21-P. Embodiments of the present disclosure are not limited thereto, and, in some embodiments, the third adhesive layer 23 and the fourth adhesive layer 24 may cover portions of the first portion A1 and the second portion A2 of the first adhesive layer 21, respectively.

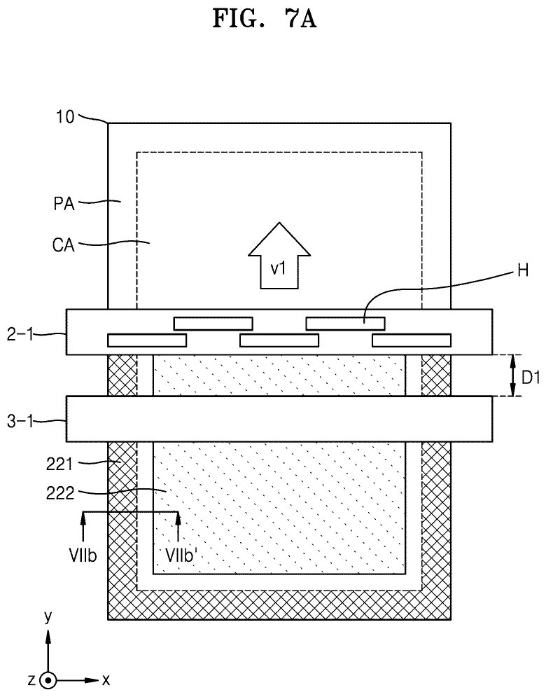

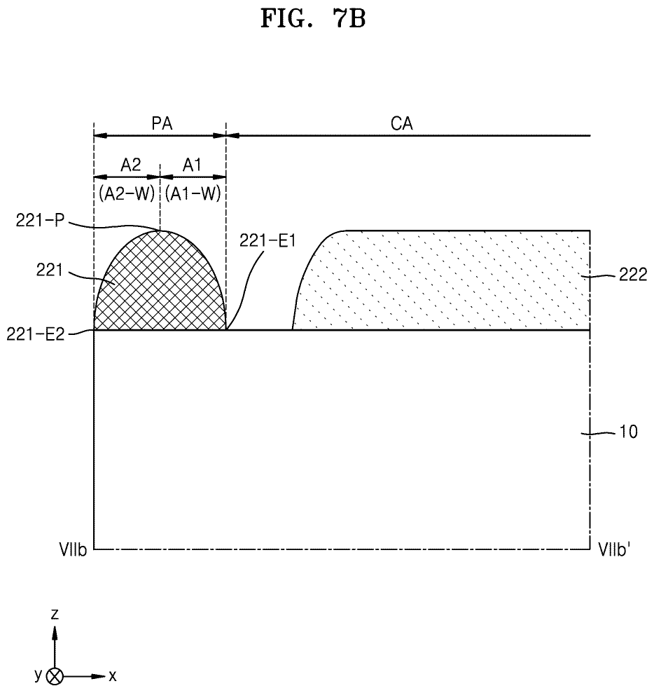

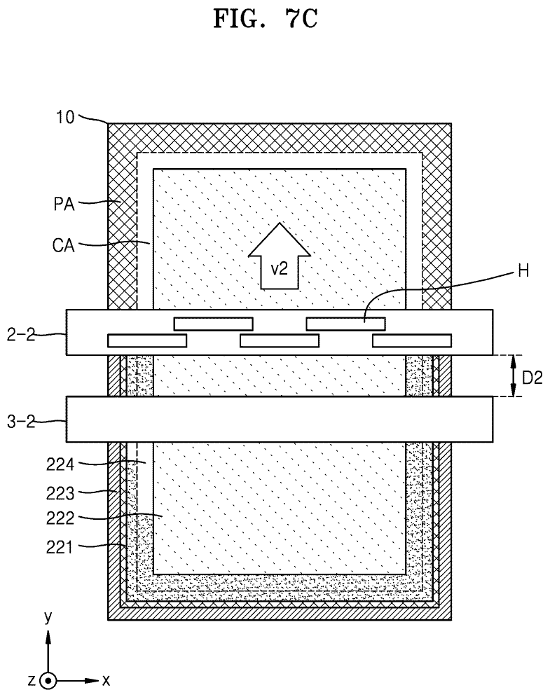

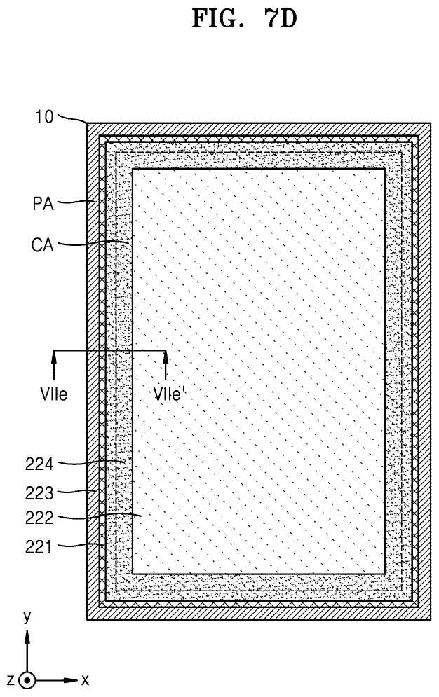

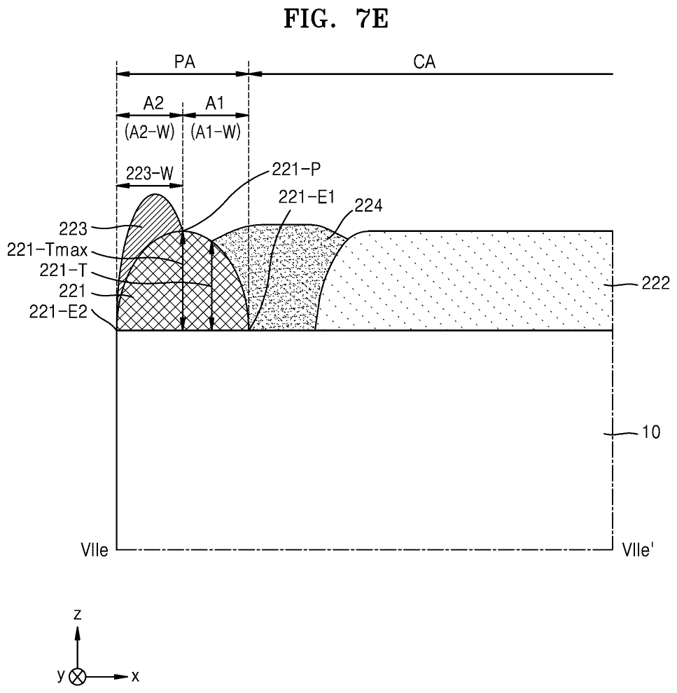

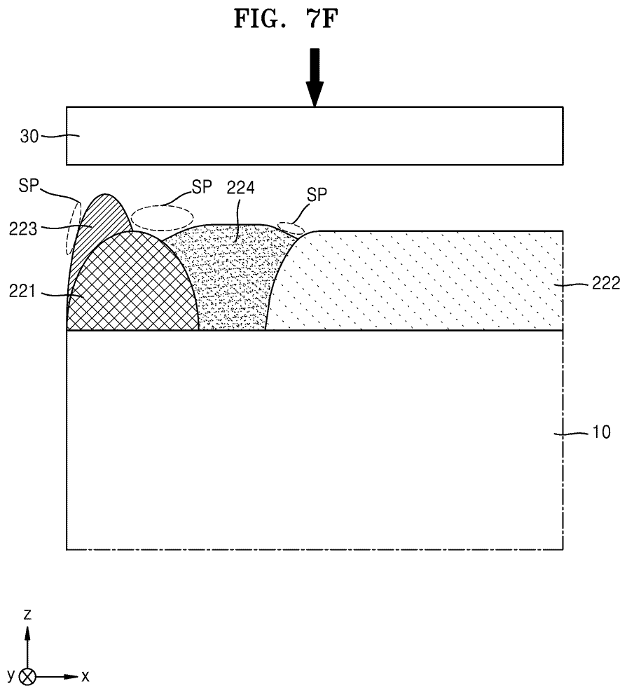

FIGS. 7A, 7C, and 7D are each a plan view of the display apparatus in a processing state of a method of manufacturing the display apparatus according to some embodiments.

FIGS. 7B, 7E, and 7F are each a cross-sectional view of the display apparatus in the processing state of the method of manufacturing the display apparatus according to some embodiments. The terms method and process may be used interchangeably herein.

FIGS. 7A and 7B are each a plan view and a cross-sectional view of the display apparatus, according to a process of forming the first adhesive material layer 221 and the second adhesive material layer 222. FIGS. 7C, 7D, and 7E are each a plan view or a cross-sectional view of the display apparatus, according to a process of forming the third adhesive material layer 223 and the fourth adhesive material layer 224. FIG. 7F is a cross-sectional view of the display apparatus according to a process of pressing the window 30. Hereinafter, in the examples, the first adhesive material layer 221, the second adhesive material layer 222, the third adhesive material layer 223, and the fourth adhesive material layer 224 may include the same material.

Hereinafter, characteristics regarding embodiments described with reference to FIGS. 5A to 5F and redundant characteristics are omitted, and descriptions below will mainly relate to differences.

Referring to FIG. 7A, the process may include forming the first adhesive material layer 221 and the second adhesive material layer 222 on the display panel 10.

The process of forming the first adhesive material layer 221 and the second adhesive material layer 222 may include applying the adhesive material through the first injection apparatus 2-1 and semi-hardening through the first hardening apparatus 3-1.

First, the process may include applying the adhesive material (e.g., OCR) included in the first adhesive material layer 221 and the second adhesive material layer 222 to the display panel 10 by using the first injection apparatus 2-1.

The process may include controlling the first injection apparatus 2-1 such that the adhesive material is injected from predetermined heads H (e.g., without being injected from other heads H), thereby correspondingly applying the first adhesive material layer 221 to the peripheral area PA of the display panel 10 and correspondingly applying the second adhesive material layer 222 to the central area CA of the display panel 10. For example, the process may include controlling some of the heads H (e.g., not all of the heads H) of the first injection apparatus 2-1 overlapping the peripheral area PA to inject the adhesive material such that the first adhesive material layer 221 is applied to the peripheral area PA. Simultaneously, for example, the process may include controlling some of the heads H (e.g., not all of the heads H) of the first injection apparatus 2-1 overlapping the central area PA to inject the adhesive material such that the second adhesive material layer 222 is applied to the central area CA. In this case, the first adhesive material layer 221 and the second adhesive material layer 222 may be apart from each other.

The process may include moving the first injection apparatus 2-1 at a certain speed (e.g., the first speed v1) along a direction (e.g., the +y direction) and injecting the adhesive material such that the first adhesive material layer 221 and the second adhesive material layer 222 are entirely and evenly applied.

Subsequently, the process may include semi-hardening the adhesive material. For example, the process may include semi-hardening the first adhesive material layer 221 and the second adhesive material layer 222 after (e.g., right after) applying the first adhesive material layer 221 and the second adhesive material layer 222 by injecting the adhesive material by using the first injection apparatus 2-1.

The process may include controlling the first hardening apparatus 3-1 and the first injection apparatus 2-1 such that the first hardening apparatus 3-1 is apart from the first injection apparatus 2-1 by a certain distance (e.g., the first distance D1) and follows the first injection apparatus 2-1 at a constant speed (e.g., the first speed v1). The first adhesive material layer 221 and the second adhesive material layer 222 which are semi-hardened by irradiating the first adhesive material layer 221 and the second adhesive material layer 222 with light by using the first hardening apparatus 3-1, may have a certain elastic modulus and may maintain a certain shape. In an example, based on the semi-hardening, the first adhesive material layer 121 the second adhesive material layer 122 may maintain the shape until a subsequent process.

FIG. 7B is a cross-sectional view of the display apparatus taken along line VIIb-VIIb′ of FIG. 7A.

Referring to FIG. 7B, the process may include disposing and semi-hardening the first adhesive material layer 221 and the second adhesive material layer 222 on the display panel 10 such that the first adhesive material layer 121 and the second adhesive material layer 222 maintain a certain shape. The process may include arranging the first adhesive material layer 221 correspondingly to the peripheral area PA. The process may include arranging the second adhesive material layer 222 correspondingly to the central area CA.

The thickness of the first adhesive material layer 221 may be variable (e.g., may not be constant). For example, the thickness of the first adhesive material layer 221 may change along the ±x direction. A portion where the thickness of the first adhesive material layer 221 is greatest may be defined as a peak 221-P of the first adhesive material layer 221. Among the edges of the first adhesive material layer 221, the edge adjacent to the central area CA may be defined as a first edge 221-E1. An edge located on the opposite side of the first edge 221-E1 among the edges of the first adhesive material layer 221 may be defined as a second edge 221-E2. In this case, a portion of the first adhesive material layer 221 arranged between the peak 221-P and the first edge 221-E1 may be referred to as the first portion A1, and a portion of the first adhesive material layer 221 arranged between the peak 221-P and the second edge 221-E2 may be referred to as the second portion A2. In an embodiment, the cross-sectional shape of the first adhesive material layer 221 may be substantially semicircular and the width A1-W of the first portion A1 may be substantially equal to the width A2-W of the second portion A2.

Referring to FIG. 7C, the process may include forming the third adhesive material layer 223 and the fourth adhesive material layer 224 on the display panel 10 described with reference to the embodiment illustrated in FIG. 7A.

The process of forming the third adhesive material layer 223 and the fourth adhesive material layer 224 may include applying the adhesive material through the second injection apparatus 2-2 and semi-hardening through the second hardening apparatus 3-2.

First, the process may include applying the adhesive material included in the third adhesive material layer 223 and the fourth adhesive material layer 224 to the display panel 10 of the embodiment illustrated in FIG. 7A by using the second injection apparatus 2-2. In an embodiment, the adhesive material included in the third adhesive material layer 223 and the fourth adhesive material layer 224 may be the same adhesive material (e.g., OCR) as the material included in the first adhesive material layer 221 and the second adhesive material layer 222. In an embodiment, the process may include simultaneously applying the third adhesive material layer 223 and applying the fourth adhesive material layer 224.

Similarly to the process of applying the first adhesive material layer 221 and the second adhesive material layer 222, the process may include applying the third adhesive material layer 223 and the fourth adhesive material layer 224 according to a desired shape by controlling the heads H of the second injection apparatus 2-2. For example, the process may include controlling the second injection apparatus 2-2 such that the heads H of the second injection apparatus 2-2 inject the adhesive material to apply the third adhesive material layer 223 overlappingly on the first adhesive material layer 221, and such that the heads H inject the adhesive material to apply the fourth adhesive material layer 224 overlappingly on the first adhesive material layer 221 and the second adhesive material layer 222. In this case, the process may include controlling the second injection apparatus 2-2 such that the adhesive substance is prevented from being injected by (e.g., is not injected from) a certain portion of the heads H, thereby separating the third adhesive material layer 223 and the fourth adhesive material layer 224 from each other.

The process may include moving the second injection apparatus 2-2 at a certain speed (e.g., the second speed v2) along a direction (e.g., the +y direction) and injecting the adhesive material using the second injection apparatus 2-2, such that the third adhesive material layer 223 and the fourth adhesive material layer 224 are entirely and evenly applied. In some embodiments, the second speed v2 may be equal to the first speed v1 (FIG. 7A). In some other embodiments the second speed v2 may be different from the first speed v1.

Subsequently, for example, the process may include semi-hardening the adhesive material. For example, the process may include semi-hardening the third adhesive material layer 223 and the fourth adhesive material layer 224 after (e.g., immediately after, after one or more intervening operations) applying the third adhesive material layer 223 and the fourth adhesive material layer 224 by injecting the adhesive material by using the second injection apparatus 2-2.

The process may include emitting light of a predetermined wavelength band using the second hardening apparatus 3-2, while controlling the second hardening apparatus 3-2 and the second injection apparatus 2-2. For example, the process may include moving the second hardening apparatus 3-2 and the second injection apparatus 2-2, such that the second hardening apparatus 3-2 is apart from the second injection apparatus 2-2 by a certain distance (e.g., the second distance D2) and follows the second injection apparatus 2-2 at a constant speed (e.g., the second speed v2). In some embodiments, the second distance D2 may be different from the first distance D1 (FIG. 7A). For example, the second distance D2 may be less than the first distance D1 (FIG. 5A). The third adhesive material layer 223 and the fourth adhesive material layer 224, which are semi-hardened by irradiating the first adhesive material layer 221 and the second adhesive material layer 222 with light by using the second hardening apparatus 3-2, may have a certain elastic modulus and may maintain a certain shape. In an example, based on the semi-hardening, the third adhesive material layer 123 and the fourth adhesive material layer 224 may maintain the shape until a subsequent process.

In the process of emitting light by using the second hardening apparatus 3-2, the process may include exposing the third adhesive material layer 222 and the third adhesive material layer 224 to light irradiated by the second hardening apparatus 3-2, and further, exposing the first adhesive material layer 221 and the second adhesive material layer 222, to the light irradiated by the second hardening apparatus 3-2. Thus, the first adhesive material layer 221 and the second adhesive material layer 222 may show an effect of having been semi-hardened twice. In an example, the elastic modulus of the first adhesive material layer 221 and second adhesive material layer 222 may be different from the elastic modulus of the third adhesive material layer 223 and fourth adhesive material layer 224.

Referring to FIG. 7D, the process may include disposing the first adhesive material layer 221, the second adhesive material layer 222, the third adhesive material layer 223, and the fourth adhesive material layer 224 on the display panel 10.

The process may include semi-hardening the first adhesive material layer 221, the second adhesive material layer 222, the third adhesive material layer 223, and the fourth adhesive material layer 224 such that each maintains a certain shape. The process may include disposing and semi-hardening the first adhesive material layer 221 and the third adhesive material layer 223 such that the first adhesive material layer 221 and the third adhesive material layer 223 correspond to the peripheral area PA and have a frame shape surrounding the central area CA. The process may include arranging the second adhesive material layer 222 correspondingly to the central area CA such that the second adhesive material layer 222 covers a portion of the central area CA. The process may include arranging the fourth adhesive material layer 224 correspondingly to the first adhesive material layer 221 and the second adhesive material layer 222, and the fourth adhesive material layer 224 may have an approximate frame shape surrounding the second adhesive material layer 222.

The first adhesive material layer 221 and the second adhesive material layer 222 may be apart from each other. The second adhesive material layer 222 and the third adhesive material layer 223 may be apart from each other. The third adhesive material layer 222 and the fourth adhesive material layer 224 may be apart from each other, and a portion of the first adhesive material layer 221 may be exposed in an area wherein the third adhesive material layer 223 and the fourth adhesive material layer 224 are apart from each other.

FIG. 7E is a cross-sectional view of the display apparatus of FIG. 7D, taken along line VIIe-VIIe′ of FIG. 7D. Referring to FIG. 7E, the process may include disposing and semi-hardening the first adhesive material layer 221, the second adhesive material layer 222, the third adhesive material layer 223, and the fourth adhesive material layer 224 on the display panel 10 while maintaining a certain shape for each of the first adhesive material layer 221, the second adhesive material layer 222, the third adhesive material layer 223, and the fourth adhesive material layer 224.

The characteristics of the first adhesive material layer 221 may be the same as described with reference to FIG. 7B.

The process may include disposing the second adhesive material layer 222 on the display panel 10 correspondingly to the central area CA. The first adhesive material layer 221 and the second adhesive material layer 222 may be apart from each other.

The process may include disposing the third adhesive material layer 223 on the display panel 10 in the peripheral area PA. For example, the process may include disposing the third adhesive material layer 223 on the first adhesive material layer 221 in the peripheral area PA.

The third adhesive material layer 223 may overlap a portion of the upper surface of the first adhesive material layer 221. In an embodiment, an edge of the third adhesive material layer 223 may contact the second edge 221-E2 of the first adhesive material layer 221 (or the edge of the display panel 10) and another edge of the third adhesive material layer 223 may contact the peak 221-P of the first adhesive material layer 221. In some embodiments, another edge of the third adhesive material layer 223 may be arranged on the second portion A2 of the first adhesive material layer 221.

The third adhesive material layer 223 may overlap the second portion A2 of the first adhesive material layer 221 in the peripheral area PA. For example, the third adhesive material layer 223 may cover a portion of the second portion A2 of the first adhesive material layer 221. In an embodiment, a width 223-W of the third adhesive material layer 223 measured from an edge of the third adhesive material layer 223 to another edge of the third adhesive material layer 223 along a direction (e.g., the ±x direction) parallel to the upper surface of the display panel 10 may be equal to or less than the width A2-W of the second portion A2.

The third adhesive material layer 223 may directly contact the second portion A2 of the first adhesive material layer 221. For example, the third adhesive material layer 223 may directly contact the upper surface of the second portion A2 of the first adhesive material layer 221 and cover at least a portion of the second portion A2.

The fourth adhesive layer 224 may be arranged between the first adhesive material layer 221 and the second adhesive material layer 222. For example, the fourth adhesive material layer 224 may fill a portion of a space between the first adhesive material layer 221 and the second adhesive material layer 222.

The fourth adhesive material layer 224 may overlap the central area CA and the peripheral area PA. In an embodiment, a portion of the fourth adhesive material layer 224 may overlap the first adhesive material layer 221 in the peripheral area PA. A portion of the fourth adhesive material layer 224 may overlap the second adhesive material layer 222 in the central area CA.

The fourth adhesive layer 224 may directly contact the first adhesive material layer 221, the second adhesive material layer 222, and the display panel 10. In an embodiment, a portion of the fourth adhesive material layer 224 may directly contact the first adhesive material layer 221 and cover a portion of the first adhesive material layer 21 in the peripheral area PA. A portion of the fourth adhesive material layer 224 may directly contact the second adhesive material layer 222 and cover a portion of the second adhesive material layer 222 in the central area CA. The fourth adhesive material layer 224 may directly contact the display panel 10 in an area wherein the first adhesive material layer 221 and the second adhesive material layer 222 are apart from each other in the central area CA.

A thickness 221-T of the first adhesive material layer 221 (or the first portion A1) covered by the fourth adhesive material layer 224 may be less than a peak thickness 221-Tmax of the first adhesive material layer 221. Accordingly, the first adhesive material layer 221 may act as a dam that prevents the fourth adhesive material layer 224 from overflowing beyond the peripheral area PA to the edge of the display panel 10.

The third adhesive material layer 223 and the fourth adhesive material layer 224 may be apart from each other. A portion of the first adhesive material layer 221 may be exposed in an area wherein the third adhesive material layer 223 and the fourth adhesive material layer 224 are apart from each other. In example of FIG. 7E, the width 223-W of the third adhesive material layer 223 is identical to the width A2-W of the second portion A2, and the portion of the third adhesive material layer 224 in which the second adhesive material layer 223 is apart from the third adhesive material layer 224 is arranged only in the first portion A1 of the first adhesive material layer 221, but embodiments are not limited thereto. In some embodiments, the width 223-W of the third adhesive material layer 223 may be less than the width A2-W of the second portion A2, and the area in which the third adhesive material layer 223 is apart from the fourth adhesive material layer 224 may be arranged in the first portion A1 and second portion A2 of the first adhesive material layer 221.

Referring to FIG. 7F, the process may include disposing the window 30 on the embodiment shown in FIG. 7E. The first adhesive material layer 221, the second adhesive material layer 222, the third adhesive material layer 223, and the fourth adhesive material layer 224 may act as adhesives that attach the display panel 10 to the window 30.

First, the process may include moving the window 30 from the +z direction to the −z direction with respect to the first adhesive material layer 221, the second adhesive material 222, the third adhesive material layer 223, and the fourth adhesive material layer 224. In this case, the upper surface of the display panel 10 and the lower surface of the window 30 may be parallel to each other. For example, the process may include arranging the display panel 10 and the window 30 such that the upper surface of the display panel 10 and the lower surface of the window 30 are parallel to the +x direction and the −x direction.

After moving the window 30 in the −z direction such that the window 30 contacts the upper surface of the third adhesive material layer 223, the process may include applying pressure (e.g., continuously applying pressure) in the −z direction. Since the third adhesive material layer 223 is semi-hardened, which is a state that is not completely hardened, the pressure applied in the −z direction may deform the form of the third adhesive material layer 223. In this case, the third adhesive material layer 223 pressed by the window 30 may be deformed and may fill the space SP between the third adhesive material layer 223 and the edge of the display panel 10.

In an example, the process may include then continuing to apply the pressure in the −z direction, and accordingly, the lower surface of the window 30 may contact the upper surface of the fourth adhesive material layer 224. The process may include continuing to apply the pressure. Since the fourth adhesive material layer 224 is semi-hardened, which is a state that is not completely hardened, the continued pressure applied in the −z direction may deform the form of the fourth adhesive material layer 224. Therefore, the fourth adhesive material layer 224 may be deformed to fill the space SP between the first adhesive material layer 221 and the fourth adhesive material layer 224 and the space SP between the second adhesive material layer 222 and the fourth adhesive material layer 224.

In an example, the process may include then continuing to apply the pressure in the −z direction, and accordingly, the lower surface of the window 30 may be in contact with the upper surface of the second adhesive material layer 222. The process may include continuing to apply the pressure. Since the second adhesive material layer 222 is semi-hardened, which is a state that is not completely hardened, the continued pressure applied in the −z direction may deform the form of the second adhesive material layer 222. Therefore, the second adhesive material layer 222 may be deformed to fill the space SP between the second adhesive material layer 222 and the fourth adhesive material layer 224.

By applying pressure in the −z direction, the process may modify the second adhesive material layer 222, the third adhesive material layer 223, and the fourth adhesive material layer 224 such that the second adhesive material layer 222, the third adhesive material layer 223, and the fourth adhesive material layer 224 fill the entire space SP, thereby completely hardening the first adhesive material layer 221, the second adhesive material layer 222, the third adhesive material layer 223, and the fourth adhesive material layer 224. The process of completely hardening the first adhesive material layer 221, the second adhesive material layer 222, the third adhesive material layer 223, and the fourth adhesive material layer 224 may include emitting light (e.g., ultraviolet light) for a certain period of time. Accordingly, the process may completely harden the first adhesive material layer 221, the second adhesive material layer 222, the third adhesive material layer 223, and the fourth adhesive material layer 224 and attach (e.g., due to the hardening) the display panel 10 to the window 30.

Through the above-described process, the display apparatus according to an embodiment illustrated in FIGS. 6A and 6B may be manufactured. In this case, the completely hardened first adhesive material layer 221, second adhesive material layer 222, third adhesive material layer 223, and fourth adhesive material layer 224 may respectively correspond to the first adhesive layer 21, the second adhesive layer 22, the third adhesive layer 23, and the fourth adhesive material layer 24 (FIG. 6B).

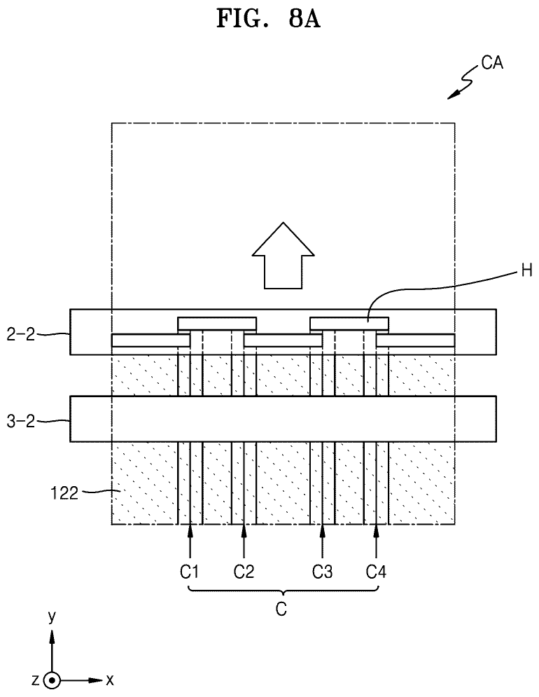

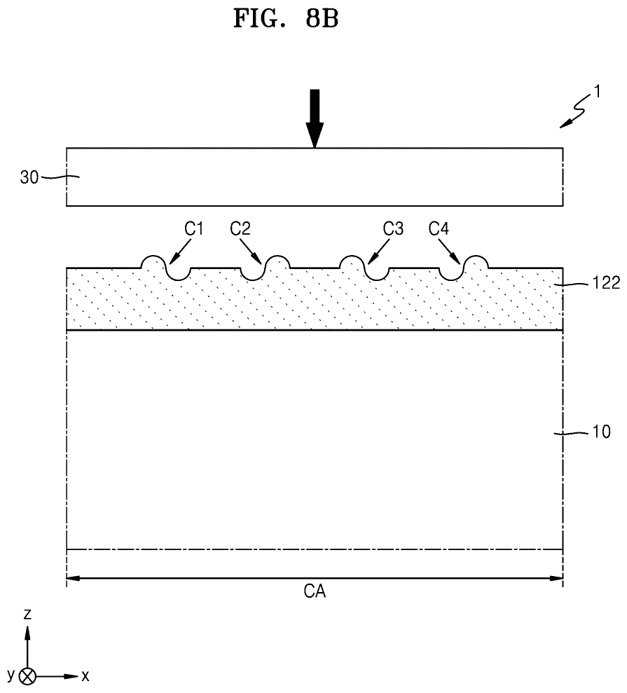

FIGS. 8A and 8B are each a plan view and a cross-sectional view of an enlarged central area in a processing state of the method of manufacturing the display apparatus according to an embodiment.

Referring to FIGS. 8A and 8B, some of the heads H of the second injection apparatus 2-2 may overlap each other in the central area CA. Thus, the adhesive material may be additionally injected in an area where heads H overlap each other. To compensate for the additional injection, the adhesive material may be controlled to be less injected in an area adjacent to the area where heads H overlap each other. For example, for an area where multiple heads H overlap each other, the method may include controlling the heads H such that the amount of the adhesive material injected by one or more of the heads H in the area is reduced. Alternatively, for example, the method may include controlling the heads H such that the amount of the adhesive material injected by one or more of the heads H adjacent the area is reduced.

Accordingly, for example, the second adhesive material layer 122 may include a plurality of curved portions C extending along the moving direction of the second injection apparatus 2-2 (e.g., the +y direction). For example, the second adhesive material layer 122 may include first to fourth curved portions C1, C2, C3, and C4 extending in the +y direction and being parallel to each other.

The first to fourth curved portions C1, C2, C3, and C4 may include a convex portion protruding (e.g., in the +y direction) more than the upper surface of the second adhesive material layer 122 parallel to the upper surface of the display panel 10 in an area wherein the heads H overlap each other and may include a concave portion adjacent to the convex portion.

When the window 30 is pressed on the second adhesive material layer 122, if the elastic modulus of the second adhesive material layer 122 is sufficiently low, the first to fourth curved portions C1, C2, C3, and C4 may be transformed by pressure and become flat. If the elastic modulus of the second adhesive material layer 122 is not sufficiently low, at least some of the first to fourth curved portions C1, C2, C3, and C4 may not become completely flat and protrusions and recesses may remain.

In this case, portions where protrusions and recesses may remain among the first to fourth curved portions C1, C2, C3, and C4 may remain in the central area CA as a striped stain, which may be recognized by the user when an image is displayed through the light-emitting diode. This case may lead to image quality deterioration of the display apparatus.

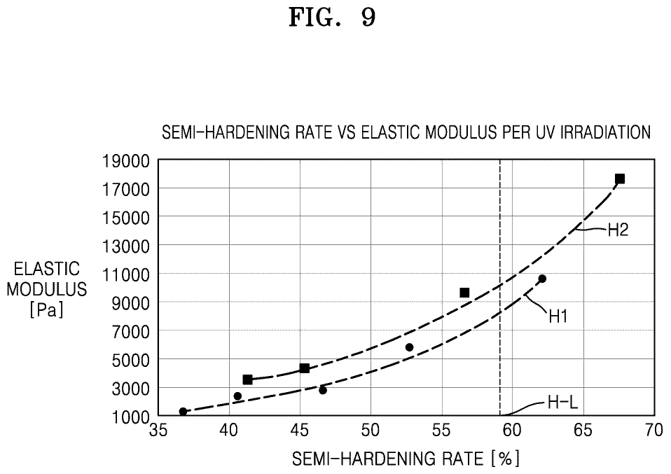

FIG. 9 is a graph showing the elastic modulus according to the semi-hardening rate in accordance with one or more embodiments of the present disclosure.

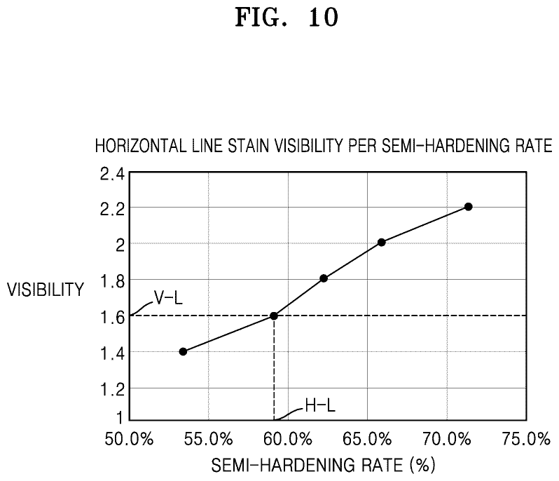

FIG. 10 is a graph showing the visibility of the striped stain according to the semi-hardening rate in accordance with one or more embodiments of the present disclosure.

Referring to FIG. 9, ultraviolet irradiation is performed once in a first embodiment H1 and ultraviolet irradiation is performed twice in a second embodiment H2.

Referring to the graph, the x-axis indicates the semi-hardening rate, and the y-axis indicates the elastic modulus of which the unit is pascal (Pa).

It can be confirmed from the first embodiment H1 and the second embodiment H2 that, as the semi-hardening rate increases, the elastic modulus increases. It can be confirmed that the elastic modulus is increased as the semi-hardening rate is increased regardless of the number of ultraviolet irradiations.

As a result of comparing the first embodiment H1 with the second embodiment H2, it is shown that the second embodiment H2, wherein the ultraviolet irradiation is performed twice, has greater semi-hardening rate and elastic modulus. For example, the semi-hardening rate of the first embodiment H1 may be about 37% to about 62%. The semi-hardening rate of the second embodiment H2 may be about 42% to about 67.5%.

If the semi-hardening rate is increased, the elastic modulus of the adhesive material layer may be increased. Since a higher elastic modulus of the adhesive material makes flattening the curve during the window pressing process more difficult, the visibility of the striped stain will be increased. As a result, the visibility of the striped stain may be increased as the semi-hardening rate is increased. A graph showing the relation between the semi-hardening rate and the visibility of the stain is illustrated in FIG. 10.

Referring to FIG. 10, the x-axis represents the semi-hardening rate and the y-axis represents the visibility, which is an arbitrary value.

A visibility level may be determined as the threshold visibility V-L. In an embodiment, the threshold visibility V-L may be set to 1.6. The semi-hardening rate corresponding to the threshold visibility V-L may be defined as the threshold semi-hardening rate H-L. In an embodiment, the threshold semi-hardening rate H-L corresponding to the threshold visibility V-L may be about 59%.

Referring to FIG. 9, the threshold semi-hardening rate H-L determined with reference to FIG. 10 is illustrated as a dotted line parallel to the y axis.

In the case of the first embodiment H1, it is shown that a range of about 88% (about 37% to about 59%) of the whole semi-hardening rate (about 37% to about 62%) is less than or equal to the threshold semi-hardening rate H-L.

In the case of the second embodiment H2, it is shown that a range of about 67% (about 42% to about 59%) of the whole semi-hardening rate (about 42% to about 67.5%) is less than or equal to the threshold semi-hardening rate H-L.

Thus, a lower number of ultraviolet irradiations leads to a greater number of embodiments corresponding to the threshold rate or less, and thus, more embodiments having stains as much as or less than the threshold visibility may be obtained.

From FIGS. 8A, 8B, 9, and 10, it is shown that reducing the number of ultraviolet irradiations is effective in decreasing the visibility of striped stains in the central area in which the image is displayed. In an embodiment shown in FIGS. 5A to 5F, it is shown that the second adhesive material layers 122 (FIG. 5C) are irradiated once with ultraviolet light. Thus, through the method of manufacturing the display apparatus according to the embodiments shown in FIGS. 5A to 5F, a display apparatus wherein the image quality is improved due to the reduction in the visibility of striped stains may be prepared.

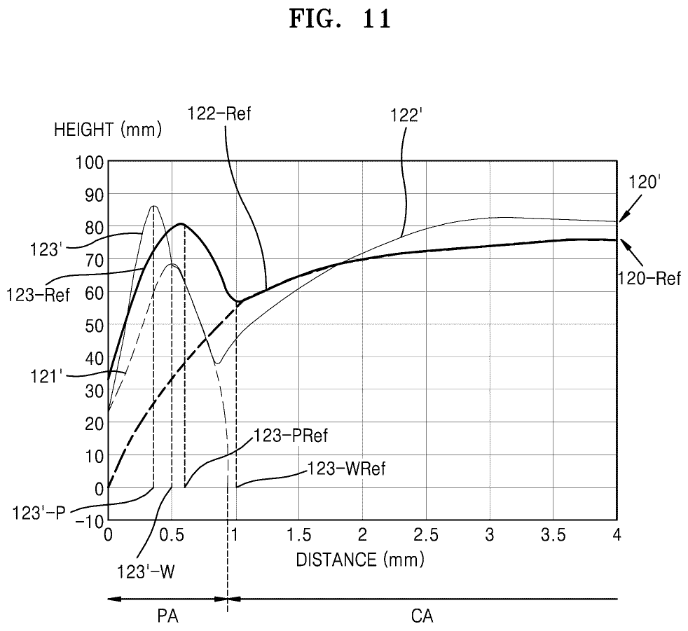

FIG. 11 is a graph showing an application profile of an adhesive material layer according to the prior art and an application profile of the adhesive material layer according to an embodiment of the disclosure.

The graph shown in FIG. 11 shows an application profile of the adhesive material layer, and for convenience of comparison with the previous embodiments, the descriptions below are provided under the assumption that the unit of distance corresponds to the x-axis and is in millimeters (mm), and the unit of height corresponds to the z-axis and is also in mm.

Referring to FIG. 11, an application profile of the adhesive material layer according to the prior art, that is, a first profile 120-Ref, is a comparative example relative to the disclosure, and is represented by a relatively thick solid line and a dashed line. The application profile of the adhesive material layer according to an embodiment supported by aspects of the present disclosure, that is, a second profile 120′, is represented by a relatively thin straight line and a dashed line.

The second profile 120′ may, for example, represent the embodiment illustrated in FIG. 5E.

The z value of the upper surface of the display panel is 0 and may be a straight line parallel to the x axis.

The x value of the edge of the display panel is 0 and may be a straight line parallel to the z axis.

A first profile 120-Ref may include a second portion 122-Ref represented by a solid line and a dashed line and overlapping the entire central area CA and peripheral area PA and a third portion 123-Ref arranged on the second portion 122-Ref and represented by a solid line.

The second profile 120′ may include a first portion 121′ represented by a solid line and a dashed line and corresponding to the peripheral area PA, a second portion 122′ represented by a solid line and corresponding to the central area, and a third portion 123′ represented by a solid line and disposed on the first portion 121′. The first portion 121′, the second portion 122′, and the third portion 123′ may correspond to the first adhesive material layer 121, the second adhesive material layer 122, and the third adhesive material layer 123 (FIG. 5E), respectively.

The second portion 122-Ref of the first profile 120-Ref may overlap the entire central area Ca and the peripheral area PA and may extend to the edge of the display panel or to a point wherein x=0 and z=0. A portion of the second portion 122-Ref may be covered by the third portion 123-Ref. A portion of the second portion 122-Ref covered by the third portion 123-Ref is represented as a dashed line.

The third portion 123-Ref of the first profile 120-Ref may overlap a portion of the central area CA and the peripheral area PA and be disposed on the second portion 122-Ref. A peak 123-PRef of the third portion 123-Ref may be disposed at an approximate point wherein x=0.6 mm and z=80.5 mm. An edge of the third portion 123-Ref may be arranged at an edge of the display panel or an approximate point wherein x=0 and z=35 mm, and another edge of the third portion 123-Ref may be arranged at an approximate point wherein x=1.0 mm and on the second portion 122-Ref. Thus, a width 123-WRef of the third portion 123-Ref along the x axis direction may be about 1.0 mm.

The first portion 121′ of the second profile 120′ overlaps the peripheral area PA and may be arranged from the edge of the display panel to a boundary between the peripheral area PA and the central area CA. For example, the first portion 121′ may be arranged between the edge of the display panel or a point wherein x=0 and z=25 mm and the boundary between the peripheral area PA and the central area CA or a point wherein x=0.9 mm and z=0. The width of the first portion 121′ according to the X axis direction may be substantially equal to the width of the peripheral area PA. For example, the width of the first portion 121′ may be about 0.9 mm.

The second portion 122′ of the second profile 120′ may overlap the entire central area CA and a portion of the second portion 122′ may extend to the peripheral area PA to cover a portion of the first portion 121′. A portion of the first portion 121′ covered by the second portion 122′ is represented as a dashed line.

The third portion 123′ of the second profile 120′ may be disposed on the first portion 121′ in the peripheral area PA. A portion of the first portion 121′ covered by the third portion 123′ is represented as a dashed line.

An edge of the third portion 123′ of the second profile 120′ may be arranged in an edge of the display panel or arranged approximately at x=0, z=25 mm. Another edge of the third portion 123′ may be arranged at a peak of the first portion 121′ or at an approximate point wherein x=0.5 mm and z=68 mm. Thus, a width 123′-W of the third portion 123′ along the x axis direction may be about 0.5 mm. A peak 123′-P of the third portion 123′ may be arranged at an approximate point wherein x=0.4 mm and z=86 mm.

The width 123′-W of the third portion 123-Ref of the first profile 120-Ref may be about 1.0 mm and may be greater than the width of the peripheral area PA, which is 0.9 mm. Thus, a portion of the third portion 123-Ref of the first profile 120-Ref may be arranged in the central area CA.

The width 123′-W of the third portion of the second profile 120′ may be about 0.5 mm and may be less than the width of the peripheral area PA, which is 0.9 mm. Thus, the third portion 123′ of the second profile 120′ may not include the portion arranged in the central area CA.

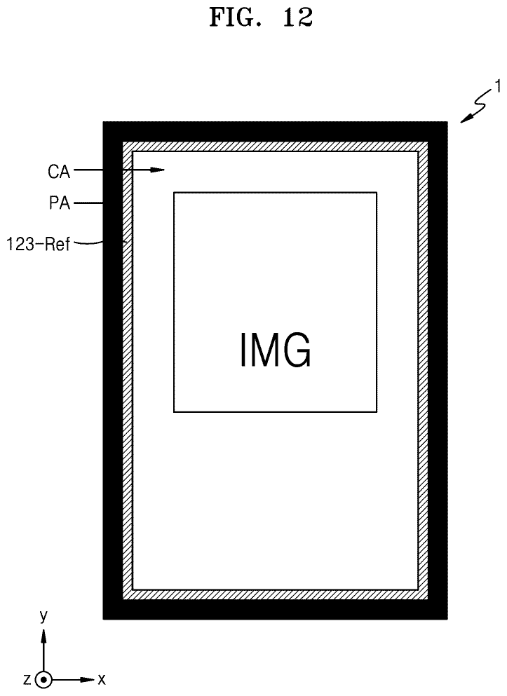

FIG. 12 is a plan view of a display apparatus manufactured by applying the adhesive material layer according to the prior art. For example, the embodiment shown in FIG. 12 may be a display apparatus manufactured by arranging the adhesive material layer according to the first profile 120-Ref of FIG. 11.

Referring to FIGS. 11 and 12, the display apparatus 1 may include a central area CA displaying an image IMG and a peripheral area PA surrounding the central area CA and not displaying an image. A portion that emits light and is substantially visible to the user may be the central area CA. As described with reference to FIG. 11, the width 123-WRef of the third portion 123-Ref of the first profile 120-Ref may be greater than the width of the peripheral area PA. Accordingly, a portion of the third portion 123-Ref of the first profile 120-Ref may be extend to the central area CA. Thus, a portion of the third portion 123-Ref of the first profile 120-Ref may be visible as an approximately frame-shaped stain in the central area CA. This case may lead to image quality deterioration of the display apparatus 1.

In an example case of the second profile 120′ in which the adhesive material is arranged according to an embodiment, the width 123′-W of the third portion 123′ of the second profile 120′ is less than the width of the peripheral area PA, and thus, does not extend to the central area CA. Accordingly, when the display apparatus 1 is manufactured by arranging the adhesive material according to the embodiment, the adhesive material layer may not be visible in the display apparatus 1 wherein the image IMG is displayed, thereby preventing image deterioration of the display apparatus 1.

As described above, according to the embodiments, the width of an adhesive arranged in the peripheral area may be decreased. Accordingly, the contour of the adhesive layer in the central area wherein the image is displayed may be prevented from being a striped shape that is visible. In some aspects, the area wherein the image is displayed may be increased by reducing the width of the peripheral area and increasing the width of the central area without being affected by the contour of the adhesive layer being visible.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a central area and a peripheral area surrounding the central area;
a window disposed on the display panel;
a first adhesive layer between the display panel and the window and arranged along the peripheral area of the display panel;
a second adhesive layer between the display panel and the window and corresponding to the central area of the display panel; and
a third adhesive layer between the display panel and the window and overlapping a portion of an upper surface of the first adhesive layer in the peripheral area of the display panel.

2. The display apparatus of claim 1, wherein the second adhesive layer and the third adhesive layer are apart from each other.

3. The display apparatus of claim 1, wherein,
in a cross-sectional view, the first adhesive layer includes:
a peak where a thickness of the first adhesive layer is greatest,
a first portion between the peak and a first edge adjacent to the central area, and
a second portion between the peak and a second edge arranged opposite to the first edge, wherein
the second adhesive layer overlaps the first portion, and
the third adhesive layer overlaps the second portion.

4. The display apparatus of claim 3, wherein, a peak width of the third adhesive layer is less than or equal to a width of the second portion.

5. The display apparatus of claim 3, wherein
the second adhesive layer directly contacts an upper surface of the first portion, and
the third adhesive layer directly contacts an upper surface of the second portion.

6. The display apparatus of claim 1, further comprising a fourth adhesive layer between the display panel and the window and between the first adhesive layer and the second adhesive layer.

7. The display apparatus of claim 6, wherein the fourth adhesive layer directly contacts an upper surface of a portion of the first adhesive layer and directly contacts an upper surface of a portion of the second adhesive layer.

8. The display apparatus of claim 1, wherein, in a plan view, at least one of the first adhesive layer and the third adhesive layer surrounds the central area.

9. A method of manufacturing a display apparatus, the method comprising:
in a display panel comprising a central area and a peripheral area surrounding the central area, arranging a first adhesive material layer along the peripheral area of the display panel;
arranging a second adhesive material layer such that the second adhesive material layer overlaps the central area and a first portion of the first adhesive material layer; and
arranging a third adhesive material layer on a second portion of the first adhesive material layer opposite to the first portion, wherein the third adhesive material layer is apart from the second adhesive material layer.

10. The method of claim 9, wherein,
in a cross-sectional view, the first adhesive material layer comprises:
a peak where a thickness is greatest,
the first portion between a peak and a first edge adjacent to the central area, and
the second portion between the peak and a second edge opposite to the first edge,
the second adhesive material layer directly contacts an upper surface of the first portion, and
the third adhesive material layer directly contacts an upper surface of the second portion.

11. The method of claim 10, wherein a distance measured from an edge of the third adhesive material layer to another edge of the third adhesive material layer along a direction parallel to the upper surface of the display panel is less than or equal to a width of the second portion.

12. The method of claim 9, wherein, in a plan view, at least one of the first adhesive material layer and the third adhesive material layer surrounds the central area.

13. The method of claim 9, further comprising:
semi-hardening the first adhesive material layer by irradiating the first adhesive material layer with light; and
semi-hardening the second adhesive material layer and the third adhesive material layer by irradiating the second adhesive material layer and the third adhesive material layer with the light, wherein
an elastic modulus of the semi-hardened second adhesive material layer and an elastic modulus of the semi-hardened third adhesive material layer are different from an elastic modulus of the semi-hardened first adhesive material layer.

14. A method of manufacturing a display apparatus, the method comprising:
in a display panel comprising a central area and a peripheral area surrounding the central area, arranging a first adhesive material layer along the peripheral area of the display panel;
arranging a second adhesive material layer on the display panel apart from the first adhesive material layer and correspondingly to the central area;
arranging a third adhesive material layer on the first adhesive material layer; and
arranging a fourth adhesive material layer between the first adhesive material layer and the second adhesive material layer.

15. The method of claim 14, wherein in a cross-sectional view, the first adhesive material layer comprises:
a peak where a thickness is greatest,
a first portion between the peak and a first edge adjacent to the central area, and
a second portion between the peak and a second edge opposite to the first edge.

16. The method of claim 15, wherein
the third adhesive material layer directly contacts an upper surface of the second portion, and
the fourth adhesive material layer directly contacts an upper surface of the first portion.

17. The method of claim 15, wherein a distance measured from an edge of the third adhesive material layer to another edge of the third adhesive material layer along a direction parallel to an upper surface of the display panel is less than or equal to a width of the second portion.

18. The method of claim 14, wherein the second adhesive material layer and the third adhesive material layer are apart from each other.

19. The method of claim 14, further comprising:
semi-hardening the first adhesive material layer and the second adhesive material layer by irradiating the first adhesive material layer and the second adhesive material layer with light; and
semi-hardening the third adhesive material layer and the fourth adhesive material layer by irradiating the third adhesive material layer and the fourth adhesive material layer with the light.

20. The method of claim 19, wherein an elastic modulus of the semi-hardened first adhesive material layer and an elastic modulus of the semi-hardened second adhesive material layer are different from an elastic modulus of the semi-hardened third adhesive material layer and an elastic modulus of the semi-hardened fourth adhesive material layer.
